(19) United States
(12) Patent Application Publication
(10) Pub. No.: US 2026/0013285 A1
(43) Pub. Date: Jan. 8, 2026

(54) MICROFLUIDIC TRANSFER SUBSTRATE AND METHOD FOR TRANSFERRING LIGHT-EMITTING ELEMENTS

(71) Applicant: HKC CORPORATION LIMITED, SHENZHEN (CN)

(72) Inventors: Zeyao LI, SHENZHEN (CN); Pei XU, SHENZHEN (CN)

(73) Assignee: HKC CORPORATION LIMITED, SHENZHEN (CN)

(21) Appl. No.: 19/243,759

(22) Filed: Jun. 20, 2025

(30) Foreign Application Priority Data
Jul. 2, 2024 (CN) 202410876330.0

(51) Int. Cl. H10H 29/03; H01L 21/683; H10H 29/01

(52) U.S. Cl. CPC H10H 29/03; H01L 21/6835; H01L 2221/68363; H10H 29/012

(57) ABSTRACT

A microfluidic transfer substrate includes a transfer area and a liquid droplet input area. The transfer area includes a plurality of pixel groups. Each pixel group includes at least three first pixel units. One first pixel unit of each pixel group serves as a first microfluidic pixel and a surface of the first microfluidic pixel defines an assembly groove. The plurality of pixel groups include first color pixel groups, second color pixel groups, and third color pixel groups. The liquid droplet input area includes a first color liquid droplet input area, a second color liquid droplet input area, and a third color liquid droplet input area, which are configured to generate and transport liquid droplets containing a first color light-emitting element, a second color light-emitting element, and a third color light-emitting element to the transfer area, respectively. A method for transferring the light-emitting elements is further provided.

### CROSS-REFERENCE TO RELATED APPLICATIONS

The present application claims priority to Chinese Patent Application No. 202410876330.0, entitled “MICROFLUIDIC TRANSFER SUBSTRATE AND METHOD FOR TRANSFERRING LIGHT-EMITTING ELEMENTS”, filed on Jul. 2, 2024, which is herein incorporated by reference in its entirety.

### TECHNICAL FIELD

The present disclosure relates to the field of display technologies, and in particular to a microfluidic transfer substrate and a method for transferring light-emitting elements.

### BACKGROUND

With the advancement of light-emitting diode (LED) technology, micro-LED display technology is emerging as a revolutionary next-generation technology. The micro-LED is a display technology that miniaturizes and matrixes traditional LED structures, and achieves address control and individual driving of each pixel point through a driving backplane. Due to its superior performance in brightness, lifespan, contrast, response time, and other indicators compared to a liquid crystal display (LCD) and an organic light-emitting diode display (OLED), the micro-LED has been regarded by many manufacturers as the next-generation display technology, and the manufacturers have begun to actively layout the micro-LED.

However, a core technical challenge in the industrialization of the micro-LED is the mass transfer technology of micro-LED components. In related art, there is a problem of difficulty in simultaneously transferring multiple light-emitting elements with different colors to the driving backplane.

### SUMMARY OF THE DISCLOSURE

A technical solution in the present disclosure is to provide a microfluidic transfer substrate. The microfluidic transfer substrate includes a transfer area and a liquid droplet input area.

The transfer area includes a plurality of pixel groups. Each pixel group includes at least three first pixel units, and the first pixel units of each pixel groups are arranged around a center point; one first pixel unit of each pixel group serves as a first microfluidic pixel and a surface of the first microfluidic pixel defines an assembly groove, and the other first pixel units serve as second microfluidic pixels and a surface of each second microfluidic pixel is free of the assembly groove; and the plurality of pixel groups include first color pixel groups, second color pixel groups, and third color pixel groups.

The liquid droplet input area is disposed around the transfer area.

The liquid droplet input area includes a first color liquid droplet input area, a second color liquid droplet input area, and a third color liquid droplet input area that are distributed along circumference of the transfer area; and the first color liquid droplet input area is configured to generate and transport a first liquid droplet containing a first color light-emitting element to the transfer area, the second color liquid droplet input area is configured to generate and transport a second liquid droplet containing a second color light-emitting element to the transfer area, and the third color liquid droplet input area is configured to generate and transport a third liquid droplet containing a third color light-emitting element to the transfer area.

In some embodiments, the plurality of pixel groups are arranged in a two-dimensional array, each pixel group includes four first pixel units, and the four first pixel units of the same pixel group are arranged to form a two-dimensional array with two rows and two columns.

The liquid droplet input area includes a plurality of second pixel units, and all first pixel units in the transfer area and all second pixel units in the liquid droplet input area are arranged in the two-dimensional array.

The first microfluidic pixels of the same column of pixel groups are all belong to the first pixel units of the same column.

The first color liquid droplet input area and the second color liquid droplet input area are located on two opposite sides of the transfer area along a column direction, respectively.

In some embodiments, a size of the transfer area along a row direction is greater than a size of the transfer area along the column direction, and two third color liquid droplet input areas are located on two opposite sides of the transfer area along the row direction, respectively.

In some embodiments, the first color liquid droplet input area includes a first color liquid droplet generation area and a first color liquid droplet entry area that is connected to the first color liquid droplet generation area and the transfer area.

The second color liquid droplet input area includes a second color liquid droplet generation area and a second color liquid droplet entry area that is connected to the second color liquid droplet generation area and the transfer area.

The third color liquid droplet input area includes a third color liquid droplet generation area and a third color liquid droplet entry area that is connected to the third color liquid droplet generation area and the transfer area.

In some embodiments, the transfer area is rectangular, and includes a first long side and a second long side opposite to each other, as well as a first short side and a second short side opposite to each other.

The first color liquid droplet entry area is connected to the transfer area on the first long side; and a part of the first color liquid droplet generation area is located on a side of the first color liquid droplet entry area away from the transfer area, and the other part of the first color liquid droplet generation area is located in an angle area that is defined by an extension line of the first long side and an extension line of the first short side.

The second color liquid droplet entry area is connected to the transfer area on the second long side; and a part of the second color liquid droplet generation area is located on a side of the second color liquid droplet entry area away from the transfer area, and the other part of the second color liquid droplet generation area is located in an angle area defined by an extension line of the second long side and an extension line of the second short side.

In one of two third color liquid droplet input areas, the third color liquid droplet entry area is connected to the transfer area on the first short side; and a part of the third color liquid droplet generation area is located on a side of the third color liquid droplet entry area away from the transfer area, and the other part of the third color liquid droplet generation area is located in an angle area that is defined by the extension line of the second long side and the extension line of the first short side.

In the other of the two third color liquid droplet input areas, the third color liquid droplet entry area is connected to the transfer area on the second short side; and a part of the third color liquid droplet generation area is located on a side of the third color liquid droplet entry area away from the transfer area, and the other part of the third color liquid droplet generation area is located in an angle area that is defined by the extension line of the first long side and the extension line of the second short side.

In some embodiments, the microfluidic transfer substrate further includes a blank area.

The blank area is disposed around the transfer area and connected to the transfer area.

Another technical solution in the present disclosure is to provide a method for transferring light-emitting elements. The method for transferring light-emitting elements includes the following operations:
providing a microfluidic transfer substrate of any one of above embodiments;
placing liquid and corresponding color light-emitting element in the first color liquid droplet input area, the second color liquid droplet input area, and the third color liquid droplet input area, respectively; and
controlling the first color liquid droplet input area, the second color liquid droplet input area, and the third color liquid droplet input area to generate and transport liquid droplets containing corresponding color light-emitting elements to the transfer area, controlling each of the liquid droplets containing corresponding color light-emitting elements to enter an area where the corresponding color pixel group is located, and driving each of the liquid droplets containing corresponding color light-emitting elements to rotate around a center point of the corresponding color pixel group, so as to assemble each of the light-emitting elements into the assembly groove of the corresponding color pixel group.

In some embodiments, the controlling the first color liquid droplet input area, the second color liquid droplet input area, and the third color liquid droplet input area to generate and transport liquid droplets containing corresponding color light-emitting elements to the transfer area, controlling each of the liquid droplets containing corresponding color light-emitting elements to enter an area where the corresponding color pixel group is located, and driving each of the liquid droplets containing corresponding color light-emitting elements to rotate around a center point of the corresponding color pixel group, so as to assemble each of the light-emitting elements into the assembly groove of the corresponding color pixel group, includes the following operations:
controlling the first color liquid droplet input area to generate and transport the first liquid droplet containing the first color light-emitting element to the transfer area, so that the area where each of the first color pixel groups is located has the first liquid droplet; and simultaneously controlling the second color liquid droplet input area to generate and transport the second liquid droplet containing the second color light-emitting element to the transfer area, so that the area where each of the second color pixel groups is located has the second liquid droplet;
driving the first liquid droplet to rotate around a center point of each of the first color pixel groups, so as to assemble the first color light-emitting element into the assembly groove of each of the first color pixel groups; and simultaneously driving the second liquid droplet to rotate around a center point of the second color pixel group, so as to assemble the second color light-emitting element into the assembly groove of each of the second color pixel groups;
controlling the third color liquid droplet input area to generate and transport the third liquid droplet containing the third color light-emitting element to the transfer area, so that the area where each of the third color pixel groups is located has the third liquid droplet; and
driving the third liquid droplet to rotate around a center point of the third color pixel group, so as to assemble the third color light-emitting element into the assembly groove of each of the third color pixel groups.

In some embodiments, before the controlling the third color liquid droplet input area to generate and transport the third liquid droplet containing the third color light-emitting element to the transfer area, so that the area where each of the third color pixel groups is located has the third liquid droplet, the method for transferring the light-emitting elements further includes: first detecting assembly yield and supplementing assembly.

After the driving the third liquid droplet to rotate around a center point of the third color pixel group, so as to assemble the third color light-emitting element into the assembly groove of each of the third color pixel groups, the method for transferring the light-emitting elements further includes: second detecting assembly yield and supplementing assembly.

In some embodiments, before the controlling the third color liquid droplet input area to generate and transport the third liquid droplet containing the third color light-emitting element to the transfer area, so that the area where each of the third color pixel groups is located has the third liquid droplet, the method for transferring the light-emitting elements further includes: first cleaning the microfluidic transfer substrate.

The first cleaning the microfluidic transfer substrate, includes: controlling the liquid droplet input area to generate first light-emitting element-free liquid droplets; and controlling the first light-emitting element-free liquid droplets to enter the transfer area from a plurality of different directions in a staggered manner.

After the driving the third liquid droplet to rotate around a center point of the third color pixel group, so as to assemble the third color light-emitting element into the assembly groove of each of the third color pixel groups, the method for transferring the light-emitting elements further includes: second cleaning the microfluidic transfer substrate.

The second cleaning the microfluidic transfer substrate, includes: controlling the liquid droplet input area to generate second light-emitting element-free liquid droplets; and controlling the second light-emitting element-free liquid droplets to enter the transfer area from the plurality of different directions in the staggered manner.

In some embodiments, the controlling the first light-emitting element-free liquid droplets to enter the transfer area from a plurality of different directions in a staggered manner, includes:
controlling the first light-emitting element-free liquid droplets to enter the transfer area from the plurality of different directions in the staggered manner, and then enter the blank area after traversing the transfer area.

The controlling the second light-emitting element-free liquid droplets to enter the transfer area from the plurality of different directions in the staggered manner, includes the following operations:
controlling the second light-emitting element-free liquid droplets that are generated in the first color liquid droplet input area and the second color liquid droplet input area to enter the transfer area along a column direction, and then enter the blank area after traversing the transfer area; and
controlling the second light-emitting element-free liquid droplets that are generated in one third color liquid droplet input area to enter the transfer area along a row direction, and then enter the other third color liquid droplet input area that is opposite to the one third color liquid droplet input area after traversing the transfer area.

Yet another technical solution in the present disclosure is to provide a microfluidic transfer substrate including a transfer area and a liquid droplet input area. The transfer area includes a plurality of pixel groups. Each pixel group includes at least three first pixel units, and the first pixel units of each pixel groups are arranged around a center point; one first pixel unit of each pixel group serves as a first microfluidic pixel and a surface of the first microfluidic pixel defines an assembly groove, and the other first pixel units serve as second microfluidic pixels and a surface of each second microfluidic pixel is free of the assembly groove; and the plurality of pixel groups include first color pixel groups, second color pixel groups, and third color pixel groups. The liquid droplet input area includes a first color liquid droplet input area, a second color liquid droplet input area, and a third color liquid droplet input area. The first color liquid droplet input area is configured to generate and transport a first liquid droplet containing a first color light-emitting element to the transfer area, the second color liquid droplet input area is configured to generate and transport a second liquid droplet containing a second color light-emitting element to the transfer area, and the third color liquid droplet input area is configured to generate and transport a third liquid droplet containing a third color light-emitting element to the transfer area.

### BRIEF DESCRIPTION OF THE DRAWINGS

In order to more clearly illustrate the technical solutions in some embodiments of the present disclosure or in the related art, hereinafter, the accompanying drawings that are used in the description of some embodiments or the related art will be briefly described. Obviously, the accompanying drawings in the description below are merely the accompanying drawings in some embodiments of the present disclosure. For those of ordinary skill in the art, other accompanying drawings may be obtained based on these accompanying drawings without any creative efforts.

FIG. 1 is a structural block view of a microfluidic transfer device in the present disclosure.

FIG. 2 is a structural schematic view of a first embodiment of a microfluidic transfer substrate in the present disclosure.

FIG. 3 is a structural schematic view of a pixel group of the microfluidic transfer substrate of FIG. 2.

FIG. 4 is a cross-sectional structural schematic view of the microfluidic transfer substrate of FIG. 2.

FIG. 5 is a structural schematic view of the microfluidic transfer substrate of FIG. 2 after assembling light-emitting elements.

FIG. 6 is a cross-sectional structural schematic view of a structure of FIG. 5.

FIG. 7 is a structural schematic view of a second embodiment of the microfluidic transfer substrate in the present disclosure.

FIG. 8 is a structural block view of a microfluidic transfer apparatus in the present disclosure.

FIG. 9 is a flowchart of an embodiment of a method for transferring light-emitting elements in the present disclosure.

FIG. 10 is a structural schematic view of a structure corresponding to an operation at block S2 of FIG. 9.

FIG. 11 is a flowchart of a first embodiment of an operation at block S3 in the method for transferring the light-emitting elements of FIG. 9.

FIG. 12 is a structural schematic view of a structure corresponding to an operation at block S31 of FIG. 11.

FIG. 13 is a structural schematic view of a structure corresponding to an operation at block S32 of FIG. 11.

FIG. 14 is a structural schematic view of a structure corresponding to an operation at block S33 of FIG. 11.

FIG. 15 is a structural schematic view of a structure corresponding to an operation at block S34 of FIG. 11.

FIG. 16 is a flowchart of a second embodiment of the operation at block S3 in the method for transferring the light-emitting elements of FIG. 9.

FIG. 17 is a structural schematic view of a structure corresponding to a first embodiment of an operation at block S32A of FIG. 16.

FIG. 18 is a flowchart of an embodiment of an operation at block S33A of FIG. 16.

FIG. 19 is a structural schematic view of a structure corresponding to an operation at block S332A of FIG. 18.

FIG. 20 is a structural schematic view of a structure corresponding to an embodiment of an operation at block S35A of FIG. 16.

FIG. 21 is a flowchart of an embodiment of an operation at block S36A of FIG. 16.

FIG. 22 is a structural schematic view of a structure corresponding to an embodiment of an operation at block S362A of FIG. 21.

FIG. 23 is a flowchart of a third embodiment of the operation at block S3 in the method for transferring the light-emitting elements of FIG. 9.

FIG. 24 is a flowchart of an embodiment of an operation at block S33B of FIG. 23.

FIG. 25 is a structural schematic view of a structure corresponding to an operation at block S332B of FIG. 24.

FIG. 26 is a flowchart of an embodiment of an operation at block S36B of FIG. 23.

FIG. 27 is a structural schematic view of a structure corresponding to an operation at block S362B of FIG. 26.

FIG. 28 is a flowchart of the operation at block S362B of FIG. 26.

### DETAILED DESCRIPTION

The technical solutions in some embodiments of the present disclosure may be clearly and completely described in conjunction with accompanying drawings in some embodiments of the present disclosure. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure.

The terms “first”, “second”, and “third” in the present disclosure are only configured to describe and cannot be understood as indicating or implying relative importance or implicitly indicating the quantity of technical features indicated. Therefore, features that are defined as “first”, “second”, and “third” may explicitly or implicitly include at least one of these features. In the description of the present disclosure, “multiple” means at least two, such as two, three, etc., unless otherwise expressly and specifically qualified. In addition, the terms “including”, “comprising”, and “having”, as well as any variations of the terms “including”, “comprising”, and “having”, are intended to cover non-exclusive inclusions. For example, a process, method, system, product, or apparatus that includes a series of operations or units is not limited to the listed operations or units, but optionally includes operations or units that are not listed, or optionally includes other operations or units that are inherent to these processes, methods, products, or apparatus.

The reference to “embodiment” in the present disclosure means that, specific features, structures, or characteristics described in conjunction with some embodiments may be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure can be combined with other embodiments.

The present disclosure mainly provides a microfluidic transfer substrate and a method for transferring light-emitting elements, so as to solve the problem of difficulty in simultaneously transferring light-emitting elements with different colors to the driving backplane in related art.

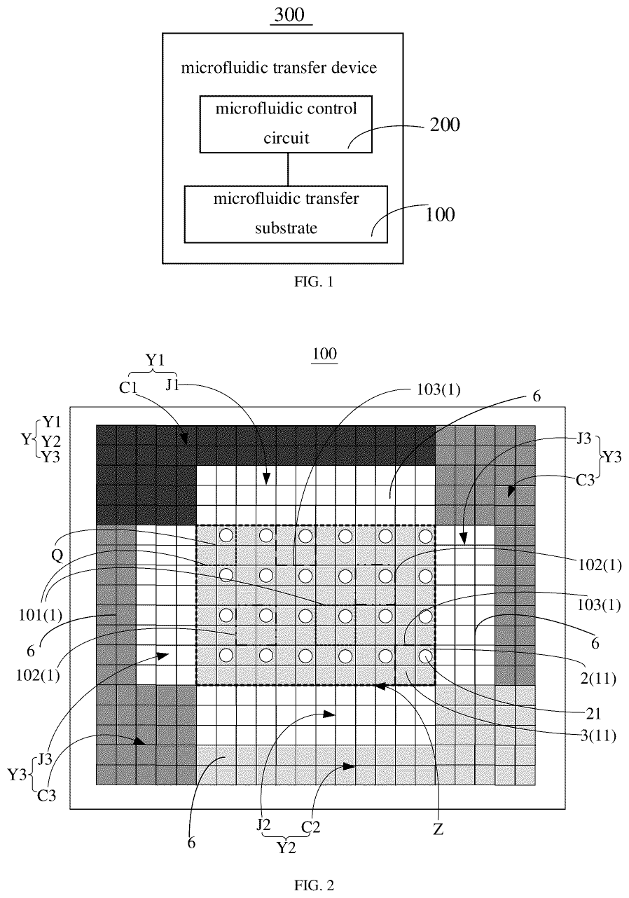

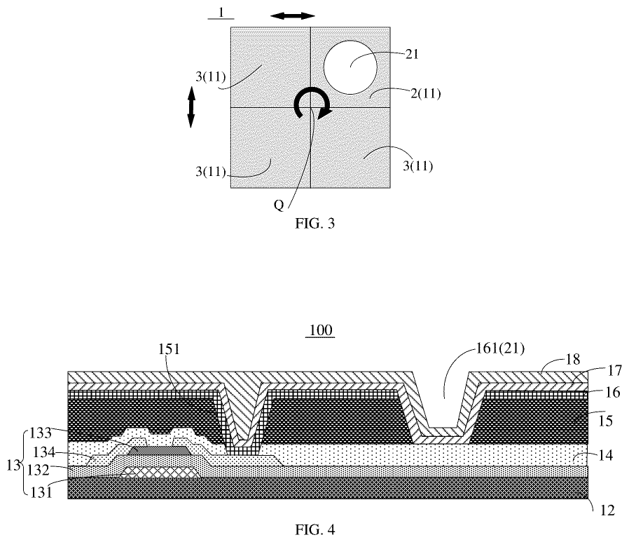

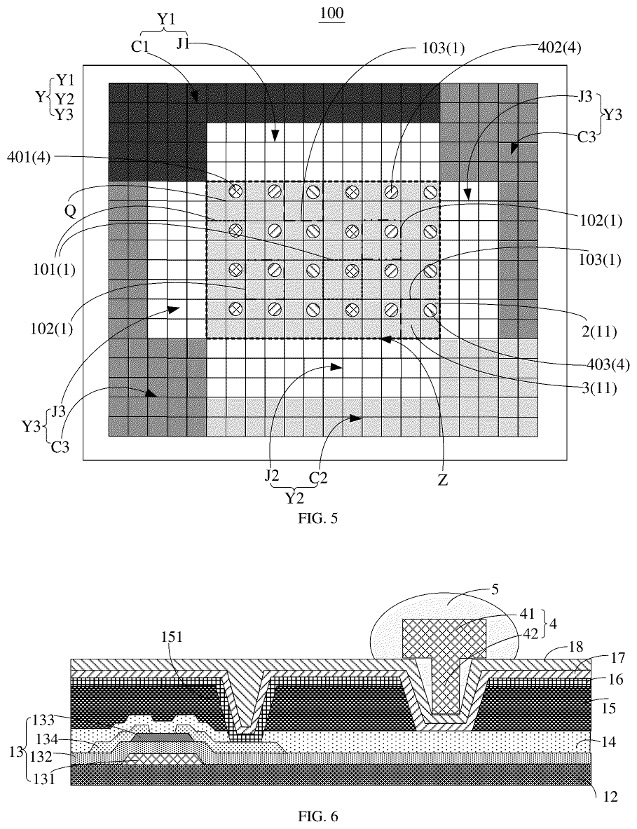

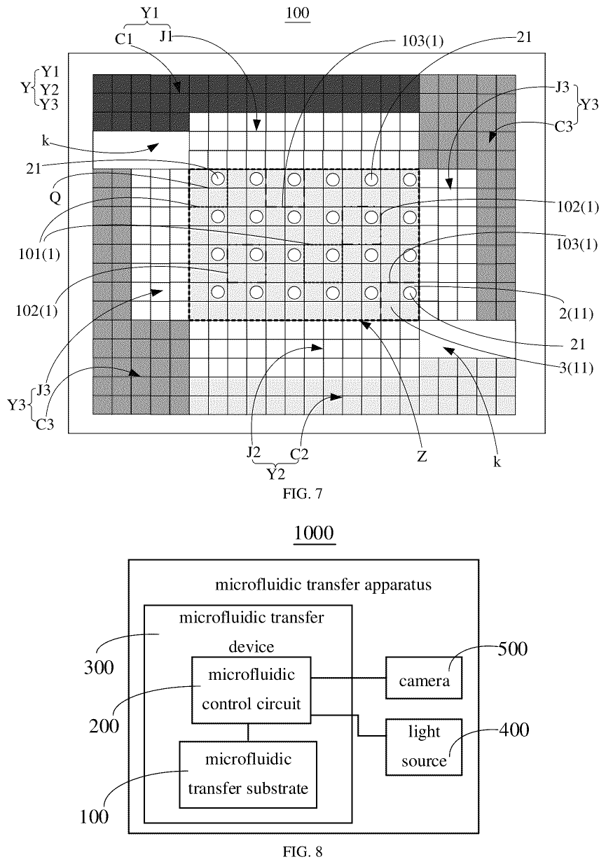

As illustrated in FIGS. 1 to 7, FIG. 1 is a structural block view of a microfluidic transfer device in the present disclosure. FIG. 2 is a structural schematic view of a first embodiment of a microfluidic transfer substrate in the present disclosure. FIG. 3 is a structural schematic view of a pixel group of the microfluidic transfer substrate of FIG. 2. FIG. 4 is a cross-sectional structural schematic view of the microfluidic transfer substrate of FIG. 2. FIG. 5 is a structural schematic view of the microfluidic transfer substrate of FIG. 2 after assembling light-emitting elements. FIG. 6 is a cross-sectional structural schematic view of a structure of FIG. 5. FIG. 7 is a structural schematic view of a second embodiment of the microfluidic transfer substrate in the present disclosure.

As illustrated in FIG. 1, the present disclosure provides a microfluidic transfer device 300, and the microfluidic transfer device 300 may be configured for mass transfer of light-emitting elements 4 with different colors. As illustrated in FIG. 1, the microfluidic transfer device 300 includes a microfluidic transfer substrate 100 and a microfluidic control circuit 200, and the microfluidic control circuit 200 is electrically connected to the microfluidic transfer substrate 100.

In some embodiments, as illustrated in FIGS. 2 and 4, the microfluidic transfer substrate 100 includes a transfer area Z and a liquid droplet input area Y. The transfer area Z has multiple pixel groups 1, and each pixel group 1 includes at least three first pixel units 11. The multiple first pixel units 11 of each pixel group 1 are arranged around a center point Q. One first pixel unit 11 of each pixel group 1 serves as a first microfluidic pixel 2, and a surface of the first microfluidic pixel 2 defines an assembly groove 21. The other first pixel units 11 serve as second microfluidic pixels 3, and a surface of each second microfluidic pixel 3 does not define the assembly groove 21. The multiple pixel groups 1 include first color pixel groups 101, second color pixel groups 102, and third color pixel groups 103.

The liquid droplet input area Y is disposed around the transfer area Z. The liquid droplet input area Y includes a first color liquid droplet input area Y1, a second color liquid droplet input area Y2, and a third color liquid droplet input area Y3 distributed along the circumference of the transfer area Z. The first color liquid droplet input area Y1 is configured to generate and transport a first liquid droplet 51 containing a first color light-emitting element 401 to the transfer area Z. The second color liquid droplet input area Y2 is configured to generate and transport a second liquid droplet 52 containing a second color light-emitting element 402 to the transfer area Z. The third color liquid droplet input area Y3 is configured to generate and transport a third liquid droplet 53 containing a third color light-emitting element 403 to the transfer area Z.

The microfluidic control circuit 200 is electrically connected to the microfluidic transfer substrate 100. The microfluidic control circuit 200 is configured to control the first color liquid droplet input area Y1, the second color liquid droplet input area Y2, and the third color liquid droplet input area Y3 to respectively generate and transport the liquid droplets 5 containing the corresponding color light-emitting elements 4 to the transfer area Z. The liquid droplet 5 containing the corresponding color light-emitting element 4 is controlled to enter an area where the corresponding color pixel group 1 is located, and the liquid droplet 5 containing the corresponding color light-emitting element 4 is driven to rotate around a center point Q of the corresponding color pixel group 1, so as to assemble the light-emitting element 4 into the assembly groove 21 of the first microfluidic pixel 2 of the corresponding color pixel group 1, completing the assembly of the light-emitting elements 4 with different colors.

In the present disclosure, the first color liquid droplet input area Y1, the second color liquid droplet input area Y2, and the third color liquid droplet input area Y3 are disposed around the transfer area Z that is assembled with the first color pixel groups 101, the second color pixel groups 102, and the third color pixel groups 103, so that the liquid droplet input areas Y with three different colors may generate and transport the liquid droplets 5 containing the corresponding color light-emitting elements 4 to the transfer area Z. This enables the assembly groove 21 of each first microfluidic pixel 2 of the pixel groups 1 with different colors in the transfer area Z is to be assembled with the corresponding color light-emitting element 4. The microfluidic transfer substrate 100 may be assembled with the first color light-emitting element 401, the second color light-emitting element 402, and the third color light-emitting element 403, achieving the assembly of the light-emitting elements 4 with the three different colors. Mass transfer of the light-emitting elements 4 with the three different colors may be achieved by using the microfluidic transfer substrate 100, effectively solving the problem of difficulty in simultaneously transferring the light-emitting elements 4 with different colors to a driving backplane in related art.

In some embodiments, as illustrated in FIGS. 2 and 3, the multiple pixel groups 1 in the transfer area Z of the microfluidic transfer substrate 100 are arranged in a two-dimensional array. Each pixel group 1 includes four first pixel units 11. The four first pixel units 11 of the same pixel group 1 are arranged to form the two-dimensional array with two rows and two columns (2×2 two-dimensional array). The liquid droplet input area Y has multiple second pixel units 6, and all first pixel units 11 of the transfer area Z and all second pixel units 6 of the liquid droplet input area Y are arranged in the two-dimensional array. The multiple second pixel units 6 in the liquid droplet input area Y and the multiple first pixel units 11 in the transfer area Z together form the two-dimensional array. The multiple second pixel units 6 in the liquid droplet input area Y are located on a row or a column where the first pixel units 11 in the transfer area Z are located. The multiple second pixel units 6 are disposed in the liquid droplet input area Y, and the second pixel units 6 are distributed in the two-dimensional array together with all first pixel units 11 in the transfer area Z. Therefore, in a case where the liquid droplet 5 containing the light-emitting element 4 generated in the liquid droplet input area Y is transported to the pixel group 1 in the transfer area Z, each second pixel unit 6 may serve as a transport channel for the liquid droplet 5, which is more convenient for the microfluidic control circuit 200 to drive the liquid droplet 5 containing the light-emitting element 4 from the liquid droplet input area Y to a position of the pixel group 1. It is conducive to shortening a transport path of the liquid droplet 5, improving the transport efficiency of the liquid droplet 5, and thereby improving the assembly efficiency of the light-emitting element 4.

In some embodiments, the liquid droplet input area Y may not have the second pixel unit 6, and the liquid droplet input area Y may be disposed only around the transfer area Z. The liquid droplets 5 containing the light-emitting elements 4 with different colors are only generated in the liquid droplet input area Y. The liquid droplets 5 containing the light-emitting elements 4 with different colors generated in the liquid droplet input area Y may move in any direction or trajectory in the liquid droplet input area Y, as long as each of the liquid droplets 5 containing the light-emitting elements 4 with different colors may be transported from the liquid droplet input area Y to the corresponding color pixel group 1 in the transfer area Z.

Alternatively, in some embodiments, the multiple first pixel units 11 of each pixel group 1 may not be distributed in an array. The multiple pixel groups 1 may be distributed arbitrarily. In some embodiments, the multiple pixel groups 1 of the microfluidic transfer substrate 100 may be spaced apart from one another and arranged to form an arbitrary shape, such as a circular ring, a triangle, a rectangular ring, or a pentagon, etc. The multiple pixel groups 1 of the microfluidic transfer substrate 100 may also be distributed discretely in a dotted pattern with intervals from one another, which may be designed as needed and may not be limited in the present disclosure.

In some embodiments, the microfluidic transfer substrate 100 may not have the liquid droplet input area Y, that is, the microfluidic transfer substrate 100 may only have the transfer area Z. The liquid droplets 5 containing the light-emitting elements 4 with different colors may be directly generated and directly transported to the area where the pixel groups 1 with different colors in the transfer area Z are located by disposing other structural components. In some embodiments, the structural component may be a print head, and the print head may be located above the microfluidic transfer substrate 100, and may move among areas corresponding to different pixel groups 1. Each of the liquid droplets 5 containing the light-emitting elements 4 with different colors may be directly dropped onto the area of the microfluidic transfer substrate 100 where the corresponding color pixel group 11 is located, so that each pixel group 1 contains one liquid droplet 5 containing the corresponding color light-emitting element 4, which facilitates the assembly of the light-emitting elements 4 with the three different colors, thereby facilitating the mass transfer of the light-emitting elements 4 with the three different colors.

As illustrated in FIG. 2, in some embodiments, the first microfluidic pixels 2 of the same column of pixel groups 1 all belong to the first pixel units 11 of the same column. In some embodiments, the positions of the first microfluidic pixels 2 of the same column of pixel groups 1 may be the same or different, but located in the first pixel units 11 of the same column. As illustrated in FIG. 2, in some embodiments, in the same column of pixel groups 1, each first microfluidic pixel 2 belongs to the first pixel unit 11 at the first row and second column of the 2×2 two-dimensional array formed by the four first pixel units 11. In some embodiments, in some pixel groups of the same column of pixel groups 1, each first microfluidic pixel 2 belongs to the first pixel unit 11 at the first row and second column of the 2×2 two-dimensional array formed by the four first pixel units 11; and in other pixel groups of the same column of pixel groups 1, each first microfluidic pixel 2 belongs to the first pixel unit 11 at the second row and second column of the 2×2 two-dimensional array formed by the four first pixel units 11.

In some embodiments, the positions of the first microfluidic pixels 2 of all pixel groups 1 in the transfer area Z are the same. In some embodiments, each first microfluidic pixel 2 of all pixel groups 1 belongs to the first pixel unit 11 at the first row and second column of the 2×2 two-dimensional array formed by the four first pixel units 11. The multiple pixel groups 1 are arranged in the array, so that in one row of two adjacent rows of first pixel units 11, all first pixel units 11 are the second microfluidic pixels 3; and in one column of two adjacent columns of first pixel units 11, all first pixel units 11 are the second microfluidic pixels 3. This may ensure that the liquid droplets 5 containing the light-emitting elements 4 with different colors that are transported from the liquid droplet input area Y to the transfer area Z may smoothly move among different pixel groups 1 the transfer area Z, which is conducive to improving the transport efficiency and assembly efficiency of the light-emitting elements 4, thereby improving the assembly accuracy.

As illustrated in FIG. 2, in some embodiments, the first color liquid droplet input area Y1 and the second color liquid droplet input area Y2 are located on two opposite sides of the transfer area Z along a column direction, respectively. The first microfluidic pixels 2 of the same column of pixel groups 1 all belong to the first pixel units 11 of the same column. Therefore, the first color liquid droplet input area Y1 may transport the first liquid droplet 51 containing the first color light-emitting element 401 to the first color pixel group 101 in the transfer area Z along the column direction. Meanwhile, the second color liquid droplet input area Y2 may transport the second liquid droplet 52 containing the second color light-emitting element 402 to the second color pixel group 102 in the transfer area Z along the column direction. The transport channel of the first liquid droplet 51 containing the first color light-emitting element 401 and the transport channel of the second liquid droplet 52 containing the second color light-emitting element 402 may not affect or interfere with each other, which is conducive to improving transport efficiency and the assembly efficiency, thereby improving the assembly accuracy.

In some embodiments, as illustrated in FIG. 2, a size of the transfer area Z along a row direction is greater than a size of the transfer area Z along the column direction. The liquid droplet input area Y includes two third color liquid droplet input areas Y3. The two third color liquid droplet input areas Y3 are located on two opposite sides of the transfer area Z along the row direction, respectively. That is, the number of the first color liquid droplet input area Y1 and the number of the second color liquid droplet input area Y2 are both one, and the first color liquid droplet input area Y1 and the second color liquid droplet input area Y2 are arranged on two opposite sides of the transfer area Z along the column direction, respectively. The number of the third color liquid droplet input area Y3 is two, and the two third color liquid droplet input areas Y3 are arranged on two opposite sides of the transfer area Z along the row direction, respectively. An area of each third color liquid droplet input area Y3 is less than an area of each of the first color liquid droplet input area Y1 and the second color liquid droplet input area Y2, which facilitates the transport of the third liquid droplet 53 containing the third color light-emitting element 403 along the row direction to the area where the third color pixel group 103 in the transfer area Z is located. A transport direction of the third liquid droplet 53 containing the third color light-emitting element 403 is different from a transport direction of each of the first liquid droplet 51 containing the first color light-emitting element 401 and the second liquid droplet 52 containing the second color light-emitting element 402.

In some embodiments, the first color is red, the second color is green, and the third color is blue, which facilitates the assembly of red light-emitting elements 4, green light-emitting elements 4, and blue light-emitting elements 4 on the microfluidic transfer substrate 100, thereby facilitating the transfer of the light-emitting elements 4 with the three colors to the driving backplane and achieving full-color display. In some embodiments, the first color, the second color, and the third color may also be other colors.

In some embodiments, as illustrated in FIG. 2, the first color liquid droplet input area Y1 includes a first color liquid droplet generation area C1 and a first color liquid droplet entry area J1 that is connected to the first color liquid droplet generation area C1 and the transfer area Z. The second color liquid droplet input area Y2 includes a second color liquid droplet generation area C2 and a second color liquid droplet entry area J2 that is connected to the second color liquid droplet generation area C2 and the transfer area Z. The third color liquid droplet input area Y3 includes a third color liquid droplet generation area C3 and a third color liquid droplet entry area J3 that is connected to the third color liquid droplet generation area C3 and the transfer area Z. The first color liquid droplet generation area C1 is configured to generate the first liquid droplet 51 containing the first color light-emitting element 401, the second color liquid droplet generation area C2 is configured to generate the second liquid droplet 52 containing the second color light-emitting element 402, and the third color liquid droplet generation area C3 is configured to generate the third liquid droplet 53 containing the third color light-emitting element 403. The first color liquid droplet entry area J1 is connected to the first color liquid droplet generation area C1 and the transfer area Z, and configured to transport the first liquid droplet 51 containing the first color light-emitting element 401 that is generated by the first color liquid droplet generation area C1 to the transfer area Z. The second color liquid droplet entry area J2 is connected to the second color liquid droplet generation area C2 and the transfer area Z, and configured to transport the second liquid droplet 52 containing the second color light-emitting element 402 that is generated by the second color liquid droplet generation area C2 to the transfer area Z. The third color liquid droplet entry area J3 is connected to the third color liquid droplet generation area C3 and the transfer area Z, and configured to transport the third liquid droplet 53 containing the third color light-emitting element 403 that is generated by the third color liquid droplet generation area C3 to the transfer area Z.

That is, each of the liquid droplets 5 containing the light-emitting elements 4 with different colors is generated in the corresponding color liquid droplet generation area and enter the transfer area Z through the corresponding color liquid droplet entry area. The liquid droplets 5 containing the light-emitting elements 4 with three different colors are transported to the transfer area Z through their respective specific areas. The generation and transport of the first liquid droplet 51 containing the first color light-emitting element 401, the second liquid droplet 52 containing the second color light-emitting element 402, and the third liquid droplet 53 containing the third color light-emitting element 403 are independent of each other and do not affect each other, which is more conducive to improving the transport efficiency, the assembly efficiency, and the assembly accuracy.

As illustrated in FIG. 2, in some embodiments, the transfer area Z is rectangular, and the size of the transfer area Z along the row direction is greater than the size of the transfer area Z along the column direction. The first color liquid droplet input area Y1, the second color liquid droplet input area Y2, and the two third color liquid droplet input areas Y3 are arranged in a rectangular ring shape and surround the transfer area Z. In some embodiments, the rectangle formed by the transfer area Z includes a first long side and a second long side opposite to each other, as well as a first short side and a second short side opposite to each other.

The first color liquid droplet entry area J1 is connected to the transfer area Z on the first long side. A part of the first color liquid droplet generating area C1 is located on a side of the first color liquid droplet entry area J1 away from the transfer area Z, and the other part of the first color liquid droplet generating area C1 is located in an angle area that is defined by an extension line of the first long side and an extension line of the first short side. That is, the first color liquid droplet entry area J1 corresponds to the first long side and is rectangular, and the first color liquid droplet generating area C1 is L-shaped. The first liquid droplet 51 containing the first color light-emitting element 401 that is generated in the first color liquid droplet generation area C1 is transported from the first color liquid droplet entry area J1 to the transfer area Z along a direction perpendicular to the first long side.

The second color liquid droplet entry area J2 is connected to the transfer area Z on the second long side. A part of the second color liquid droplet generating area C2 is located on a side of the second color liquid droplet entry area J2 away from the transfer area Z, and the other part of the second color liquid droplet generating area C2 is located in an angle area that is defined by an extension line of the second long side and an extension line of the second short side. That is, the second color liquid droplet entry area J2 corresponds to the second long side and is rectangular, and the second color liquid droplet generating area C2 is L-shaped. The first color liquid droplet generation area C1 and the second color liquid droplet generation area C2 are disposed approximately in central symmetry. The second liquid droplet 52 containing the second color light-emitting element 402 that is generated in the second color liquid droplet generation area C2 is transported from the second color liquid droplet entry area J2 to the transfer area Z along a direction perpendicular to the second long side.

In one of the two third color liquid droplet input areas Y3, the third color liquid droplet input area Y3 is connected to the transfer area Z on the first short side. A part of the third color liquid droplet generation area C3 is located on a side of the third color liquid droplet input area J3 away from the transfer area Z, and the other part of the third color liquid droplet generation area C3 is located in an angle area that is defined by the extension line of the second long side and the extension line of the first short side. In the other third color liquid droplet input area Y3, the third color liquid droplet entry area J3 is connected to the transfer area Z on the second short side. A part of the third color liquid droplet generation area C3 is located on a side of the third color liquid droplet entry area J3 away from the transfer area Z, and the other part of the third color liquid droplet generation area C3 is located in an angle area that is defined by the extension line of the first long side and the extension line of the second short side. That is, the third color liquid droplet entry area J3 of one third color liquid droplet input area Y3 corresponds to the first short side and is rectangular, and the third color liquid droplet entry area J3 of the other third color liquid droplet input area Y3 corresponds to the second short side and is rectangular. The two third color liquid droplet generation areas C3 are both L-shaped, and the two third color liquid droplet generation areas C3 are disposed approximately in central symmetry. The third liquid droplet 53 containing the third color light-emitting element 403 that is generated in one third color liquid droplet generation areas C3 is transported from the corresponding third color liquid droplet entry area J3 to the transfer area Z along a direction perpendicular to the first short side. The third liquid droplet 53 containing the third color light-emitting element 403 that is generated in the other third color liquid droplet generation areas C3 is transported from the corresponding third color liquid droplet entry area J3 to the transfer area Z along a direction perpendicular to the second short side. The liquid droplets 5 containing the light-emitting elements 4 with three different colors enter the transfer area Z from different directions, which may avoid mutual interference and improve the transport efficiency and the assembly efficiency.

As illustrated in FIG. 7, in some embodiments, the microfluidic transfer substrate 100 further includes a blank area K, and the blank area K is disposed around the transfer area Z and connected to the transfer area Z. In some implementations, after assembling the light-emitting elements 4 with three different colors onto the microfluidic transfer substrate 100, there may be problems that some light-emitting elements 4 are not properly assembled and some light-emitting elements 4 may be left in the positions of the pixel groups 1 in the transfer area Z. In order to address this, the microfluidic transfer substrate 100 needs to be clean to remove the light-emitting elements 4 that are left in the transfer area Z. This prevents the unassembled light-emitting elements 4 from being left in the transfer area Z and blocking the transport channel. By disposing the blank area K around the transfer area Z, the blank area K may be configured to accommodate the liquid droplets 5 that have cleaned the microfluidic transfer substrate 100. This may also prevent the liquid droplets 5, which may contain the light-emitting elements 4 with three different colors after cleaning, from directly returning to the first color liquid droplet input area Y1, the second color liquid droplet input area Y2, or the third color liquid droplet input area Y3. Such a return could cause the first color liquid droplet input area Y1 to be contaminated with the second color light-emitting element 402 or the third color light-emitting element 403, or the second color liquid droplet input area Y2 to be contaminated with the first color light-emitting element 401 or the third color light-emitting element 403. This contamination would affect the subsequent assembly yield.

In some embodiments, as illustrated in FIGS. 2 and 4, each of the first pixel unit 11 and the second pixel unit 6 includes a substrate 12, a thin film transistor (TFT) 13, a first insulating layer 14, a planarization layer 15, a microfluidic electrode layer 16, a second insulating layer 17, and a hydrophobic layer 18 arranged in sequence. The planarization layer 15 is an opaque layer, and the assembly groove 21 penetrates through the opaque layer.

In some embodiments, as illustrated in FIG. 4, the thin film transistor 13 is disposed on the substrate 12. The thin film transistor 13 includes a gate metal layer 131, a gate insulation layer 132, an active layer 133, and a source drain metal layer 134 stacked in sequence. The gate insulation layer 132 is disposed on a side of the gate metal layer 131 away from the substrate 12 and covers the gate metal layer 131 and the substrate 12. The active layer 133 is disposed at a position corresponding to the gate metal layer 131 and partially covers the gate insulation layer 132. The source drain metal layer 134 is disposed on a side of the active layer 133 away from the substrate 12 and covers a part of the active layer 133 and a part of the gate insulation layer 132. The source drain metal layer 134 includes a source electrode (not labeled in the figure) and a drain electrode (not labeled in the figure) arranged at intervals. A part of the active layer 133 is exposed at a position where the drain electrode and source electrode are spaced apart from each other. The first insulation layer 14 is located on a side of the source drain metal layer 134 away from the substrate 12 and covers the source drain metal layer 134, the active layer 133, and the gate insulation layer 132. The planarization layer 15, the microfluidic electrode layer 16, the second insulation layer 17, and the hydrophobic layer 18 are disposed on a surface of the first insulation layer 14 away from the substrate 12. The planarization layer 15 defines a via hole 151 spaced apart from the assembly groove 21, the via hole 151 sequentially penetrates through the planarization layer 15 and the first insulation layer 14 and expose a part of the source drain metal layer 134. The microfluidic electrode layer 16 covers the sidewall of the via hole 151 and is in contact with the source drain metal layer 134.

In some embodiments, as illustrated in FIG. 4, the planarization layer 15 is a black material layer, and the black material layer defines a through hole to expose a part of the first insulation layer 14, thereby forming the assembly groove 21.

In some embodiments, the microfluidic electrode layer 16 is a transparent conductive layer. The microfluidic electrode layer 16 may be a single continuous layer, or the microfluidic electrode layer 16 defines an opening 161 corresponding to the assembly groove 21. In some embodiments, the microfluidic electrode layer 16 may be a transparent conductive layer of indium tin oxide (ITO). As illustrated in FIG. 4, in some embodiments, the microfluidic electrode layer 16 defines the opening 161 at a position corresponding to the assembly groove 21. That is, the microfluidic electrode layer 16 is not disposed inside the assembly groove 21, and the opening 161 of the microfluidic electrode layer 16 directly exposes the assembly groove 21 and a part of the first insulation layer 14. In some embodiments, since the microfluidic electrode layer 16 is the transparent conductive layer, light may penetrate through the microfluidic electrode layer 16. Therefore, the microfluidic electrode layer 16 may not define the opening 161 at the position corresponding to the assembly groove 21, and the planarization layer 15 and the side surface and the bottom surface of the assembly groove 21 may be directly covered by the microfluidic electrode layer 16.

In some embodiments, the microfluidic electrode layer 16 may be the opaque layer, and the microfluidic electrode layer 16 defines the opening 161 at the position corresponding to the assembly groove 21. Due to the opaque nature of the microfluidic electrode layer 16, the opening 161 is defined at the position of the microfluidic electrode layer 16 corresponding to the assembly groove 21, so that the assembly groove 21 is exposed and the position of the assembly groove 21 may still transmit light.

That is, in some embodiments, the microfluidic electrode layer 16 is the transparent conductive layer, and the microfluidic electrode layer 16, the second insulation layer 17, and the hydrophobic layer 18 may all cover the bottom surface and the side surface of the assembly groove 21. In some embodiments, as illustrated in FIG. 4, the microfluidic electrode layer 16 may only be disposed on the surface of the black planarization layer 15 away from the substrate 12 and defines the opening 161 corresponding to the assembly groove 21, and the second insulation layer 17 and the hydrophobic layer 18 may all cover the bottom surface and the side surface of the assembly groove 21.

In the present embodiment, the microfluidic transfer substrate 100 only transmits light at the position of the assembly groove 21. In a case where the microfluidic control circuit 200 drives the liquid droplets 5 containing the light-emitting elements 4 with different colors to assemble each light-emitting element 4 into the corresponding assembly groove 21 of the first microfluidic pixel 2, the assembly groove 21 is filled with the light-emitting element 4. In a case where the light irradiates the microfluidic transfer substrate 100, the light passing through the assembly groove 21 may be greatly reduced, and even the position of the assembly groove 21 may no longer transmit light. Therefore, the microfluidic transfer substrate 100 may be irradiated by a light source 400 or the like, so as to detect or determine whether the light-emitting element 4 is assembled in the assembly groove 21, and accordingly the position of the first microfluidic pixel 2 that is not assembled with the light-emitting element 4 may be screened out for a subsequent operation, such as secondary assembly.

As illustrated in FIGS. 5 and 6, after transporting each of the liquid droplets 5 containing the light-emitting elements 4 with different colors to the corresponding pixel group 1 in the transfer area Z, and assembling each light-emitting element 4 into the assembly groove 21 of the first microfluidic pixel 2 of the corresponding color pixel group 1, the structure of the microfluidic transfer substrate 100 is illustrated in FIGS. 5 and 6.

As illustrated in FIG. 6, in some embodiments, the light-emitting element 4 is a light-emitting diode (LED), the light-emitting diode includes a body part 41 and a protruding part 42 protruding from the body part 41. A width of the protruding part 42 is less than that of the assembly groove 21, and a width of the body part 41 is greater than that of the assembly groove 21. After assembling the light-emitting element 4 into the assembly groove 21, the protruding part 42 is inserted into the assembly groove 21, and the body part 41 protrudes from the assembly groove 21. The width of the protruding part 42 of the light-emitting element 4 is set to be less than that of the assembly groove 21, and the width of the body part 41 is set to be greater than that of the assembly groove 21. Therefore, the protruding part 42 may be matched with the assembly groove 21, and the assembly of the light-emitting element 4 in the assembly groove 21 may be achieved by inserting the protruding part 42 into the assembly groove 21, which is more conducive to improving the assembly efficiency. After assembling the protruding part 42 into the assembly groove 21, the light-emitting element 4 is not easily detached from the assembly groove 21, which is conducive to improving the assembly yield.

In the microfluidic transfer device 300 and the microfluidic transfer substrate 100 in the present disclosure, each of the liquid droplets 5 containing the light-emitting elements 4 with different colors may be driven by the microfluidic control circuit 200 to be transported to the corresponding color pixel group 1 in the transfer area Z. Each of the liquid droplets 5 containing the light-emitting elements 4 with different colors may be driven by the microfluidic control circuit 200 through the first pixel units 11 of the pixel group 1 to swing back and forth between the first microfluidic pixel 2 and the second microfluidic pixels 3 of the corresponding color pixel group 1 or rotate around the center point Q, so as to assemble each of the light-emitting elements 4 with different colors into the corresponding assembly groove 21. The movement mode of the liquid droplet 5 driven by the microfluidic control circuit 200 makes it easier to assemble the light-emitting element 4 into the assembly groove 21 of the first microfluidic pixel 2, which is more conducive to improving the assembly yield and the assembly accuracy of the light-emitting element 4. Furthermore, it is easier to achieve mass transfer of the light-emitting elements 4 through the microfluidic transfer substrate 100 and the microfluidic transfer device 300, and achieve the assembly of the light-emitting elements 4 with different colors, thereby solving the problem of difficulty in simultaneously transferring multiple light-emitting elements 4 with different colors onto the driving backplane in related art.

As illustrated in FIG. 8, FIG. 8 is a structural block view of a microfluidic transfer apparatus in the present disclosure.

As illustrated in FIG. 8, the present disclosure further provides a microfluidic transfer apparatus 1000, which may be configured to achieve mass transfer of the light-emitting elements 4 with different colors. In some embodiments, the microfluidic transfer apparatus 1000 includes the microfluidic transfer device 300, the light source 400, and a camera 500. The microfluidic transfer device 300 may be any one of the microfluidic transfer devices 300 in the above embodiments. The light source 400 is disposed on one side of the microfluidic transfer substrate 100 of the microfluidic transfer device 300 and electrically connected to the microfluidic control circuit 200 of the microfluidic transfer device 300. The camera 500 is disposed on the other side of the microfluidic transfer substrate 100 and electrically connected to the microfluidic control circuit 200. In some embodiments, the camera 500 is a high-resolution camera 500.

In some embodiments, the microfluidic control circuit 200 is further configured to control the light source 400 to emit light and irradiate the microfluidic transfer substrate 100, control the camera 500 to capture an image of the microfluidic transfer substrate 100, and determine whether the light-emitting element 4 is assembled in the assembly groove 21 based on the image captured by the camera 500. In some embodiments, since the planarization layer 15 of the present disclosure is the opaque layer, in a case where the light-emitting element 4 is assembled in the assembly groove 21 of the first microfluidic pixel 2 of the microfluidic transfer substrate 100, and the microfluidic control circuit 200 controls the light source 400 to emit light and irradiate the microfluidic transfer substrate 100, the light passing through the assembly groove 21 may be greatly reduced or even the position of the assembly groove 21 may no longer be transparent or transmit light. In a case where some assembly grooves 21 are not assembled with the light-emitting elements 4 and the light source 400 emits light and irradiates the microfluidic transfer substrate 100, the light passing through the assembly groove 21 without the light-emitting element 4 is still sufficient. The microfluidic control circuit 200 controls the camera 500 to captured the image of the microfluidic transfer substrate 100. Based on the image, it may be clearly determined which first microfluidic pixels 2 in the multiple pixel groups 1 with different colors of the microfluidic transfer substrate 100 have not been assembled with the light-emitting elements 4 into their assembly grooves 21, and which first microfluidic pixels 2 have already had the light-emitting elements 4 assembled into their assembly grooves 21. It may determine the assembly yield of the light-emitting elements 4 on the microfluidic transfer substrate 100, so that in a case where the assembly yield does not meet the standard, the subsequent operation such as secondary assembly may be performed on the first microfluidic pixel 2 that has not been assembled with the light-emitting element 4. In some embodiments, the microfluidic control circuit 200 may control and drive the liquid droplet 5 containing the corresponding color light-emitting element 4 to supplement and assemble the corresponding color light-emitting element 4 into the assembly groove 21 that is not assembled with the corresponding color light-emitting element 4.

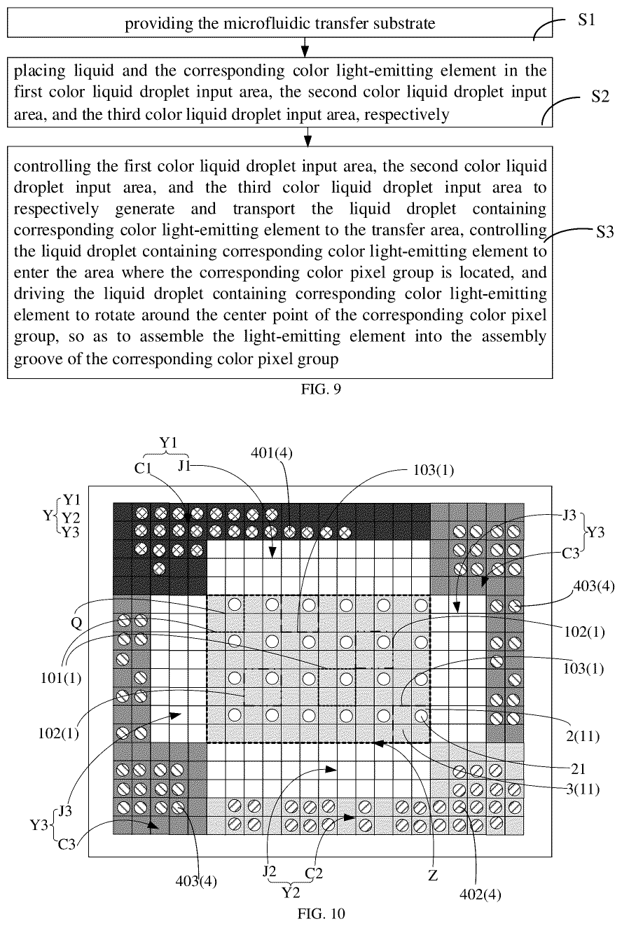

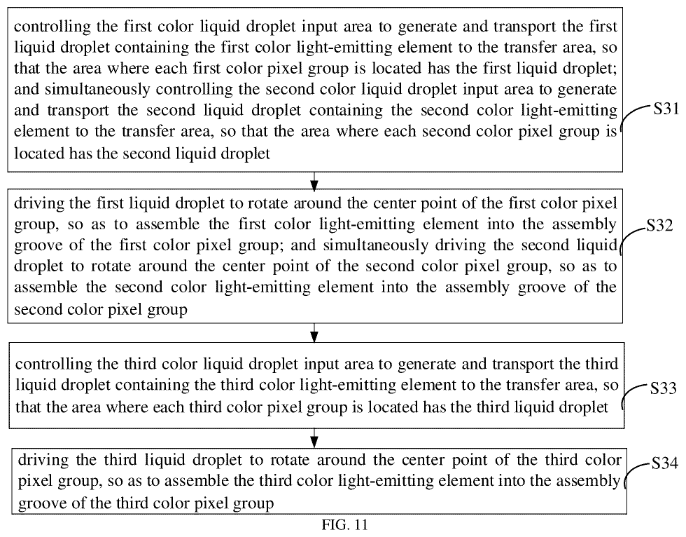

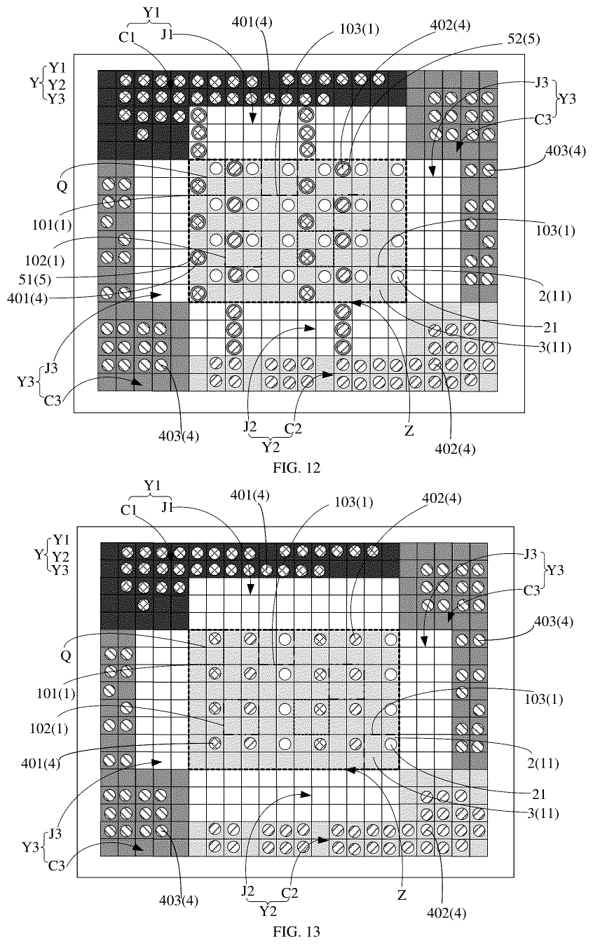

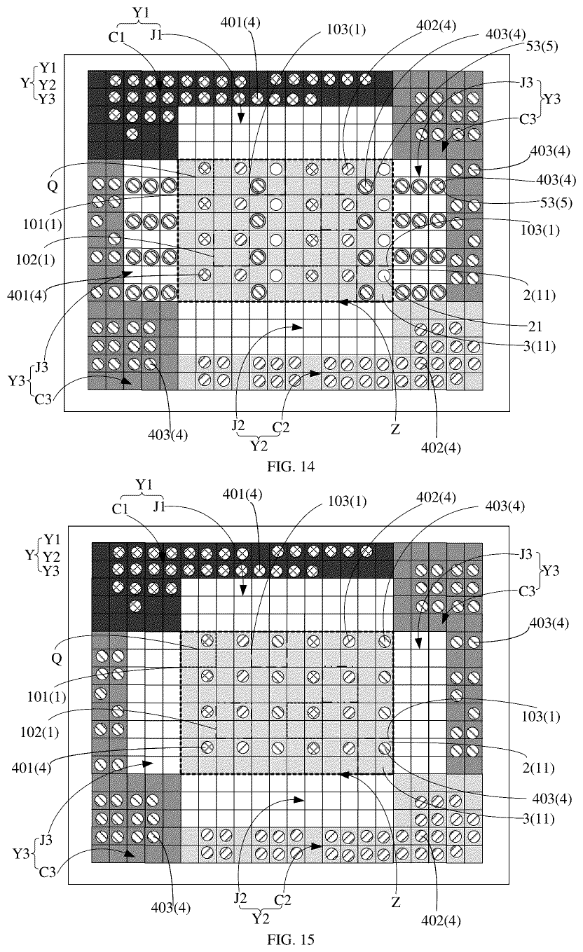

As illustrated in FIGS. 9 to 15, FIG. 9 is a flowchart of an embodiment of a method for transferring light-emitting elements in the present disclosure. FIG. 10 is a structural schematic view of a structure corresponding to an operation at block S2 of FIG. 9. FIG. 11 is a flowchart of a first embodiment of an operation at block S3 in the method for transferring the light-emitting elements of FIG. 9. FIG. 12 is a structural schematic view of a structure corresponding to an operation at block S31 of FIG. 11. FIG. 13 is a structural schematic view of a structure corresponding to an operation at block S32 of FIG. 11. FIG. 14 is a structural schematic view of a structure corresponding to an operation at block S33 of FIG. 11. FIG. 15 is a structural schematic view of a structure corresponding to an operation at block S34 of FIG. 11.

As illustrated in FIG. 9, the present disclosure further provides a method for transferring light-emitting elements 4, which is configured to achieve mass transfer of the light-emitting elements 4 with different colors. In some embodiments, the method of transferring the light-emitting elements 4 includes the following operations.

At block S1, the method of transferring the light-emitting elements 4 may include providing the microfluidic transfer substrate 100.

In some embodiments, the microfluidic transfer substrate 100 is first provided. The microfluidic transfer substrate 100 includes the microfluidic transfer substrate 100 in any one of the above embodiments. The structure of the microfluidic transfer substrate 100 is similar or identical to that of the microfluidic transfer substrate 100 in any one of the above embodiments, and they may achieve the same technical effects, which may not be repeated here.

At block S2, the method of transferring the light-emitting elements 4 may include placing liquid and the corresponding color light-emitting element 4 in the first color liquid droplet input area Y1, the second color liquid droplet input area Y2, and the third color liquid droplet input area Y3, respectively.

In some embodiments, the liquid and the first color light-emitting element 401 are placed in the first color liquid droplet input area Y1 of the microfluidic transfer substrate 100, the liquid and the second color light-emitting element 402 are placed in the second color liquid droplet input area Y2, and the liquid and the third color light-emitting element 403 are placed in the third color liquid droplet input area Y3. This facilitates subsequent generation of the liquid droplet 5 containing the corresponding color light-emitting element 4 in the first color liquid droplet input area Y1, the second color liquid droplet input area Y2, and the third color liquid droplet input area Y3, respectively.

In some embodiments, after the operation at block S2, the structure illustrated in FIG. 10 may be obtained.

At block S3, the method of transferring the light-emitting elements 4 may include controlling the first color liquid droplet input area Y1, the second color liquid droplet input area Y2, and the third color liquid droplet input area Y3 to respectively generate and transport the liquid droplet 5 containing corresponding color light-emitting element 4 to the transfer area Z, controlling the liquid droplet 5 containing corresponding color light-emitting element 4 to enter the area where the corresponding color pixel group 1 is located, and driving the liquid droplet 5 containing corresponding color light-emitting element 4 to rotate around the center point Q of the corresponding color pixel group 1, so as to assemble the light-emitting element 4 into the assembly groove 21 of the corresponding color pixel group 1.

In some embodiments, as illustrated in FIG. 11, the first microfluidic pixels 2 of the same column of pixel groups 1 of the microfluidic transfer substrate 100 all belong to the first pixel units 11 of the same column. The first color liquid droplet input area Y1 and the second color liquid droplet input area Y2 are located on two opposite sides of the transfer area Z along the column direction, respectively. In some embodiments, the operation at block S3, which involves controlling the first color liquid droplet input area Y1, the second color liquid droplet input area Y2, and the third color liquid droplet input area Y3 to respectively generate and transport the liquid droplet 5 containing corresponding color light-emitting element 4 to the transfer area Z, controlling the liquid droplet 5 containing corresponding color light-emitting element 4 to enter the area where the corresponding color pixel group 1 is located, and driving the liquid droplet 5 containing corresponding color light-emitting element 4 to rotate around the center point Q of the corresponding color pixel group 1, so as to assemble the light-emitting element 4 into the assembly groove 21 of the corresponding color pixel group 1, includes the following operations.

At block S31, the operation at block S3 may include controlling the first color liquid droplet input area Y1 to generate and transport the first liquid droplet 51 containing the first color light-emitting element 401 to the transfer area Z, so that the area where each first color pixel group 101 is located has the first liquid droplet 51; and simultaneously controlling the second color liquid droplet input area Y2 to generate and transport the second liquid droplet 52 containing the second color light-emitting element 402 to the transfer area Z, so that the area where each second color pixel group 102 is located has the second liquid droplet 52.

In some embodiments, the first microfluidic pixels 2 of the same column of pixel groups 1 of the microfluidic transfer substrate 100 all belong to the first pixel units 11 of the same column. The first color liquid droplet input area Y1 and the second color liquid droplet input area Y2 are located on two opposite sides of the transfer area Z along the column direction, respectively. Therefore, the first color liquid droplet input area Y1 and the second color liquid droplet input area Y2 may be simultaneously controlled to generate and transport the first liquid droplet 51 containing the first color light-emitting element 401 into the first color pixel group 101 of the transfer area Z along the column direction, and the second liquid droplet 52 containing the second color light-emitting element 402 into the second color pixel group 102, respectively. In this process, the transport channel of the first liquid droplet 51 containing the first color light-emitting element 401 and the transport channel of the second liquid droplet 52 containing the second color light-emitting element 402 may not affect or interfere with each other, which is conducive to improving the transport efficiency and the assembly efficiency, thereby improving the assembly accuracy.

In some embodiments, as illustrated in FIG. 12, the transfer area Z is the rectangle, and the rectangle formed by the transfer area Z includes the first long side and the second long side opposite to each other. The first color liquid droplet input area Y1 and the second color liquid droplet input area Y2 are located on two opposite sides of the transfer area Z along the column direction, respectively. The first color liquid droplet input area Y1 includes the first color liquid droplet generation area C1 and the first color liquid droplet entry area J1 that is connected to the first color liquid droplet generation area C1 and the transfer area Z. The second color liquid droplet input area Y2 includes the second color liquid droplet generation area C2 and the second color liquid droplet entry area J2 that is connected to the second color liquid droplet generation area C2 and the transfer area Z. The first color liquid droplet generation area C1 may be controlled to generate the first liquid droplet 51 containing the first color light-emitting element 401. The first color liquid droplet entry area J1 may be controlled to transport the first liquid droplet 51 containing the first color light-emitting element 401 to the transfer area Z along the direction perpendicular to the first long side, so that the area where each first color pixel group 101 is located has the first liquid droplet 51. Similarly, at the same time, the second color liquid droplet generation area C2 is controlled to generate the second liquid droplet 52 containing the second color light-emitting element 402. The second color liquid droplet entry area J2 is controlled to transport the second liquid droplet 52 containing the second color light-emitting element 402 to the transfer area Z along the direction perpendicular to the second long side, so that the area where each second color pixel group 102 is located has the second liquid droplet 52.

At block S32, the operation at block S3 may include driving the first liquid droplet 51 to rotate around the center point Q of the first color pixel group 101, so as to assemble the first color light-emitting element 401 into the assembly groove 21 of the first color pixel group 101; and simultaneously driving the second liquid droplet 52 to rotate around the center point Q of the second color pixel group 102, so as to assemble the second color light-emitting element 402 into the assembly groove 21 of the second color pixel group 102.

In some embodiments, the first liquid droplet 51 containing the first color light-emitting element 401 is driven to rotate around the center point Q of the first color pixel group 101 or swing back and forth in the four first pixel units 11 of the first color pixel group 101, so as to assemble the first color light-emitting element 401 into the assembly groove 21 of the first color pixel group 101. At the same time, the second liquid droplet 52 containing the second color light-emitting element 402 is driven to rotate around the center point Q of the second color pixel group 102 or swing back and forth in the four first pixel units 11 of the second color pixel group 102, so as to assemble the second color light-emitting element 402 into the assembly groove 21 of the second color pixel group 102. Due to the independence of the first color pixel group 101 and the second color pixel group 102, the movement of the first liquid droplet 51 and the movement of the second liquid droplet 52 do not interfere with each other. Therefore, the first liquid droplet 51 and the second liquid droplet 52 may be simultaneously driven to move.

As illustrated in FIG. 13, in some embodiments, the first color light-emitting element 401 is assembled into the assembly groove 21 of the first color pixel group 101, at the same time, the second color light-emitting element 402 is assembled into the assembly groove 21 of the second color pixel group 102, so that the structure illustrated in FIG. 13 may be obtained.

At block S33, the operation at block S3 may include controlling the third color liquid droplet input area Y3 to generate and transport the third liquid droplet 53 containing the third color light-emitting element 403 to the transfer area Z, so that the area where each third color pixel group 103 is located has the third liquid droplet 53.

In some embodiments, the third color liquid droplet input area Y3 is controlled to generate and transport the third liquid droplet 53 containing the third color light-emitting element 403 to the transfer area Z. In some embodiments, the microfluidic transfer substrate 100 includes two third color liquid droplet input areas Y3. The two third color liquid droplet input areas Y3 are located on two opposite sides of the transfer area Z along the row direction, respectively. Each third color liquid droplet input area Y includes the third color liquid droplet generation area C3 and the third color liquid droplet entry area J3 that is connected to the third color liquid droplet generation area C3 and the transfer area Z. The transfer area Z is rectangular, and includes the first short side and the second short side opposite to each other. The two third color liquid droplet entry areas J3 are connected to the transfer area Z on the first short side and the second short side, respectively. The two third color liquid droplet generation areas C3 may be controlled to generate the third liquid droplets 53 containing the third color light-emitting elements 403. The two third color liquid droplet entry areas J3 are controlled to transport the third liquid droplets 53 containing the third color light-emitting elements 403 to the transfer area Z along the direction perpendicular to the first short side and the second short side, respectively, so that the area where each third color pixel group 103 is located has the third liquid droplet 53 containing the third color light-emitting element 403.

That is, first, the first color liquid droplet input area Y1 and the second color liquid droplet input area Y2 are simultaneously controlled to generate and transport the first liquid droplet 51 containing the first color light-emitting element 401 and the second liquid droplet 52 containing the second color light-emitting element 402 to the transfer area Z. Then, the first color light-emitting element 401 is controlled to be assembled into the assembly groove 21 of the first color pixel group 101, and at the same time, the second color light-emitting element 402 is assembled into the assembly groove 21 of the second color pixel group 102. Finally, the third color liquid droplet input area Y3 is controlled to generate and transport the third liquid droplet 53 containing the third color light-emitting element 403 to the transfer area Z. That is, the transport of the third liquid droplet 53 containing the third color light-emitting element 403 occurs after the assembly of the first color light-emitting element 401 and the second color light-emitting element 402 is completed. This is to avoid interference between the movement trajectory of the third liquid droplet 53 containing the third color light-emitting element 403 and the movement trajectory of the first liquid droplet 51 and the second liquid droplet 52 (or the assembly process of the first color light-emitting element 401 and the second color light-emitting element 402) during the transport process. Such interference could otherwise result in the failure of effectively assembling each of the first color light-emitting element 401 and the second color light-emitting element 402 into the corresponding assembly groove 21 of the pixel group 1.

In some embodiments, after the operation at block S33, the structure illustrated in FIG. 14 may be obtained.

At block S34, the operation at block S3 may include driving the third liquid droplet 53 to rotate around the center point Q of the third color pixel group 103, so as to assemble the third color light-emitting element 403 into the assembly groove 21 of the third color pixel group 103.

In some embodiments, after the area where each third color pixel group 103 is located has the third liquid droplet 53, as described in the operation at block S33, the third liquid droplet 53 containing the third color light-emitting element 403 is driven to rotate around the center point Q of the third color pixel group 103 or swing back and forth in the four first pixel units 11 of the third color pixel group 103, so as to assemble the third color light-emitting element 403 into the assembly groove 21 of the third color pixel group 103, completing the assembly of the third color light-emitting element 403.

In some embodiments, after the operation at block S34, the structure illustrated in FIG. 15 may be obtained.

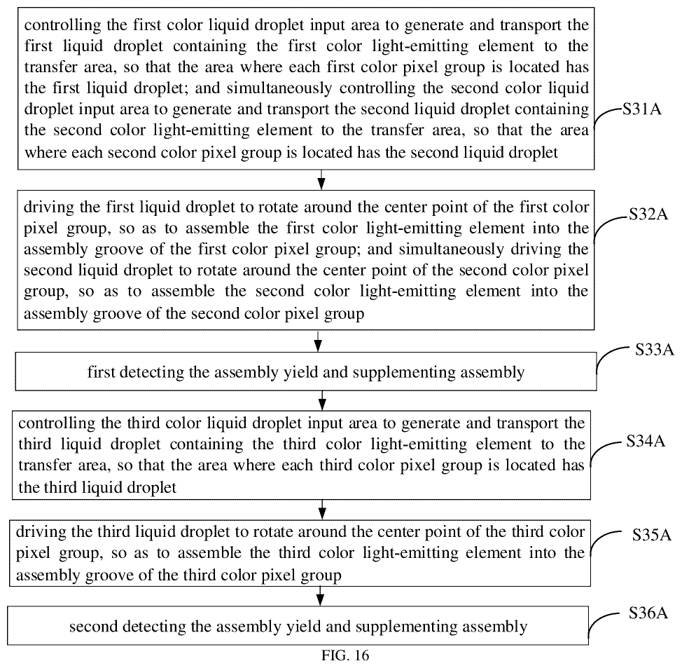

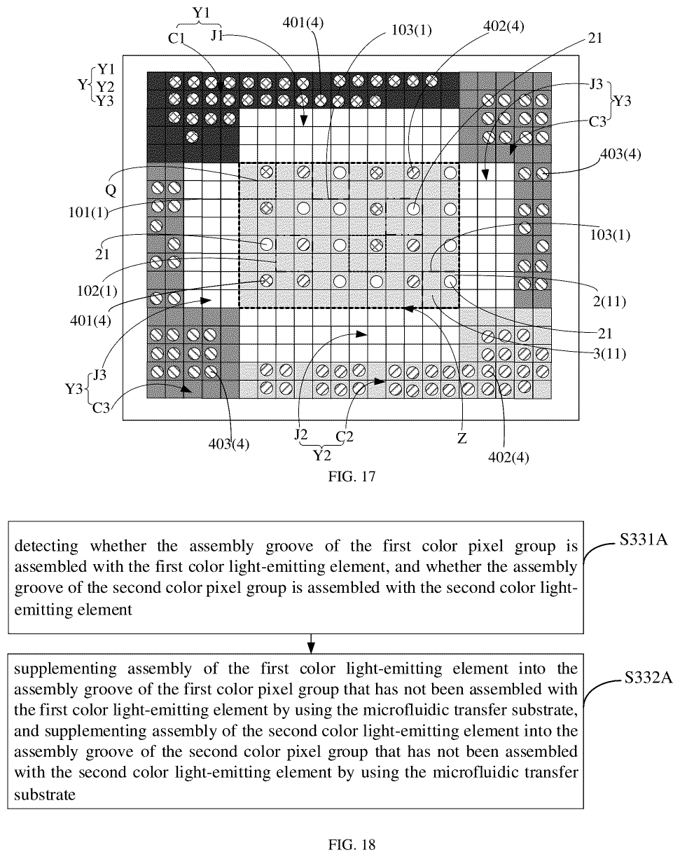

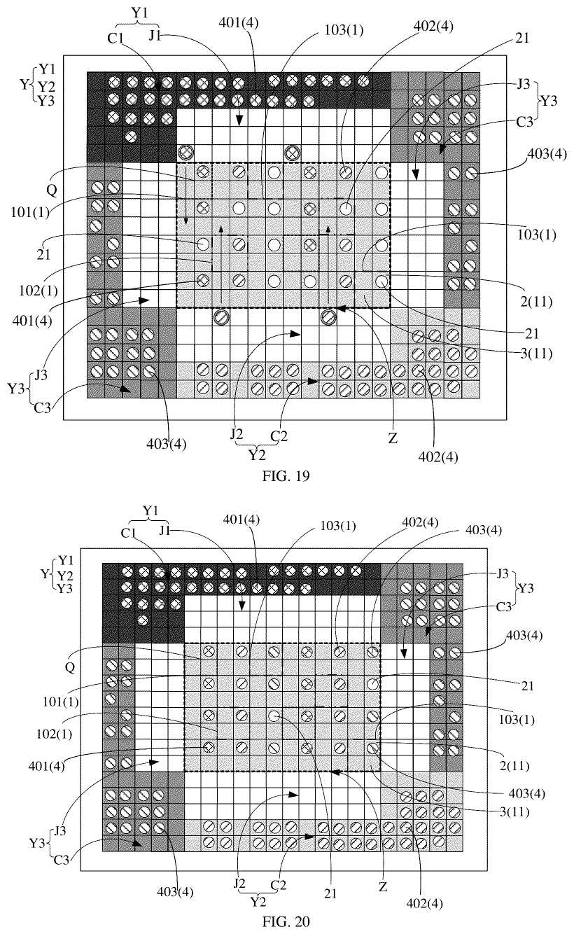

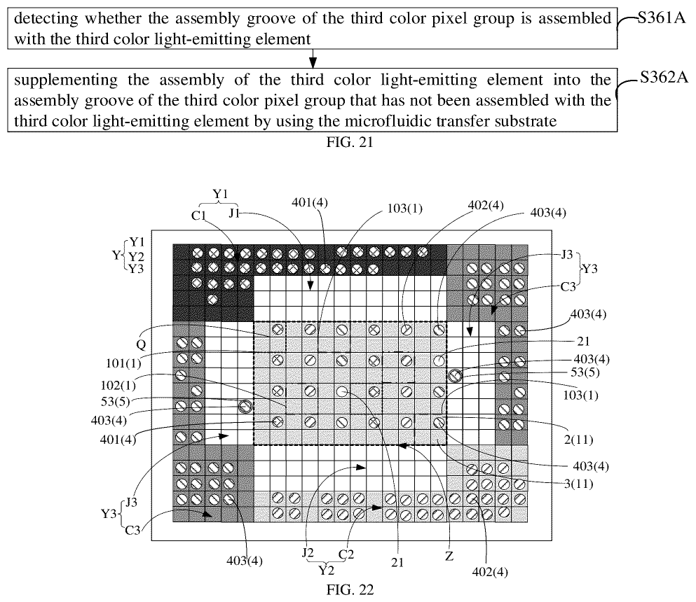

As illustrated in FIGS. 16 to 22, FIG. 16 is a flowchart of a second embodiment of the operation at block S3 in the method for transferring the light-emitting elements of FIG. 9. FIG. 17 is a structural schematic view of a structure corresponding to a first embodiment of an operation at block S32A of FIG. 16. FIG. 18 is a flowchart of an embodiment of an operation at block S33A of FIG. 16. FIG. 19 is a structural schematic view of a structure corresponding to an operation at block S332A of FIG. 18. FIG. 20 is a structural schematic view of a structure corresponding to an embodiment of an operation at block S35A of FIG. 16. FIG. 21 is a flowchart of an embodiment of an operation at block S36A of FIG. 16. FIG. 22 is a structural schematic view of a structure corresponding to an embodiment of an operation at block S362A of FIG. 21.

In some embodiments, as illustrated in FIG. 16, the operation at block S3 in the method for transferring the light-emitting elements 4, which involves controlling the first color liquid droplet input area Y1, the second color liquid droplet input area Y2, and the third color liquid droplet input area Y3 to respectively generate and transport the liquid droplet 5 containing corresponding color light-emitting element 4 to the transfer area Z, controlling the liquid droplet 5 containing corresponding color light-emitting element 4 to enter the area where the corresponding color pixel group 1 is located, and driving the liquid droplet 5 containing corresponding color light-emitting element 4 to rotate around the center point Q of the corresponding color pixel group 1, so as to assemble the light-emitting element 4 into the assembly groove 21 of the corresponding color pixel group 1, includes the following operations.

At block S31A, the operation at block S3 may include controlling the first color liquid droplet input area Y1 to generate and transport the first liquid droplet 51 containing the first color light-emitting element 401 to the transfer area Z, so that the area where each first color pixel group 101 is located has the first liquid droplet 51; and simultaneously controlling the second color liquid droplet input area Y2 to generate and transport the second liquid droplet 52 containing the second color light-emitting element 402 to the transfer area Z, so that the area where each second color pixel group 102 is located has the second liquid droplet 52.

In some embodiments, the operation at block S31A is the same as the operation at block S31 in the first embodiment of the operation at block S3 in the method for transferring the light-emitting elements 4, which may not be repeated here.

At block S32A, the operation at block S3 may include driving the first liquid droplet 51 to rotate around the center point Q of the first color pixel group 101, so as to assemble the first color light-emitting element 401 into the assembly groove 21 of the first color pixel group 101; and simultaneously driving the second liquid droplet 52 to rotate around the center point Q of the second color pixel group 102, so as to assemble the second color light-emitting element 402 into the assembly groove 21 of the second color pixel group 102.

In some embodiments, the operation at block S32A is the same as the operation at block S32 in the first embodiment of the operation at block S3 in the method for transferring the light-emitting elements 4, which may not be repeated here.

In some embodiments, after the operation at block S32A, the structure illustrated in FIG. 17 may be obtained.

At block S33A, the operation at block S3 may include first detecting the assembly yield and supplementing assembly.

In some embodiments, different from the first embodiment of the operation at block S3 in the method for transferring the light-emitting elements 4, in the present embodiment, before controlling the third color liquid droplet input area Y3 to generate and transport the third liquid droplet 53 containing the third color light-emitting element 403 to the transfer area Z, so that the area where each third color pixel group 103 is located has the third liquid droplet 53, the operation of first detecting the assembly yield and supplementing assembly, as described in the operation at block S33A, may need to be performed.

In some embodiments, as illustrated in FIG. 18, the operation of first detecting the assembly yield and supplementing assembly, as described in the operation at block S33A, includes the following operations.

At block S331A, the operation of first detecting the assembly yield and supplementing assembly may include detecting whether the assembly groove 21 of the first color pixel group 101 is assembled with the first color light-emitting element 401, and whether the assembly groove 21 of the second color pixel group 102 is assembled with the second color light-emitting element 402.

In some embodiments, since the planarization layer 15 of the microfluidic transfer substrate 100 is the opaque layer. The microfluidic transfer substrate 100 only transmits light at the position of the assembly groove 21, and does not transmit light at other positions. Therefore, the light source 400 may be configured to irradiate the microfluidic transfer substrate 100, so as to determine whether the light-emitting element 4 is assembled in the assembly groove 21.

In some embodiments, in a case where the assembly groove 21 of the first microfluidic pixel 2 of the microfluidic transfer substrate 100 is assembled with the light-emitting element 4 and the light source 400 irradiates the microfluidic transfer substrate 100, the light passing through the assembly groove 21 may be greatly reduced or even the position of the assembly groove 21 may no longer be transparent (no longer transmits light). In a case where some assembly grooves 21 are not assembled with the light-emitting elements 4 and the light source 400 irradiates the microfluidic transfer substrate 100, the light passing through the position of the assembly groove 21 without the light-emitting element 4 is still sufficient. The camera 500 captures the image of the microfluidic transfer substrate 100 under the irradiation of the light source 400. Based on the image captured by the camera 500, it may be determined whether the light-emitting element 4 is assembled in the assembly groove 21.

In some embodiments, in a case where the light passing through the assembly groove 21 of the first color pixel group 101 is greatly reduced or the position of the assembly groove 21 no longer transmits light, it may be determined that the first color light-emitting element 401 is already assembled in the assembly groove 21 of the first color pixel group 101. In a case where the light passing through the assembly groove 21 of the first color pixel group 101 is still sufficient, it may be determined that the assembly groove 21 of the first color pixel group 101 is not assembled with the first color light-emitting element 401. Similarly, whether the second color light-emitting element 402 is assembled in the assembly groove 21 of the second color pixel group 102 may also be detected using this method.

At block S332A, the operation of first detecting the assembly yield and supplementing assembly may include supplementing assembly of the first color light-emitting element 401 into the assembly groove 21 of the first color pixel group 101 that has not been assembled with the first color light-emitting element 401 by using the microfluidic transfer substrate 100, and supplementing assembly of the second color light-emitting element 402 into the assembly groove 21 of the second color pixel group 102 that has not been assembled with the second color light-emitting element 402 by using the microfluidic transfer substrate 100.

In some embodiments, in the operation at block S331A, it is detected that the assembly grooves 21 of some first color pixel groups 101 have not been assembled with the first color light-emitting elements 401 or the assembly grooves 21 of some second color pixel groups 102 have not been assembled with the second color light-emitting elements 402. The microfluidic transfer substrate 100 is configured to supplement the assembly of the first color light-emitting elements 401 into the assembly grooves 21 of the first color pixel groups 101 that have not been assembled with the first color light-emitting elements 401. The microfluidic transfer substrate 100 is also configured to supplement the assembly of the second color light-emitting elements 402 into the assembly grooves 21 of the second color pixel groups 102 that have not been assembled with the second color light-emitting elements 402. Therefore, the assembly grooves 21 of all first color pixel groups 101 and the assembly grooves 21 of all second color pixel groups 102 are assembled with corresponding color light-emitting elements 4, which is conducive to improving the assembly yield and the transfer efficiency of light-emitting elements 4.

In some embodiments, the structure corresponding to the operation at block 332A is illustrated in FIG. 19.

At block S34A, the operation at block S3 may include controlling the third color liquid droplet input area Y3 to generate and transport the third liquid droplet 53 containing the third color light-emitting element 403 to the transfer area Z, so that the area where each third color pixel group 103 is located has the third liquid droplet 53.

In some embodiments, the operation at block S34A is the same as the operation at block S33 in the first embodiment of the operation at block S3 in the method for transferring the light-emitting elements 4, which may not be repeated here.

At block S35A, the operation at block S3 may include driving the third liquid droplet 53 to rotate around the center point Q of the third color pixel group 103, so as to assemble the third color light-emitting element 403 into the assembly groove 21 of the third color pixel group 103.

In some embodiments, the operation at block S35A is the same as the operation at block S34 in the first embodiment of the operation at block S3 in the method for transferring the light-emitting elements 4, which may not be repeated here.

In some embodiments, after the operation at block S35A, the structure illustrated in FIG. 20 may be obtained.

At block S36A, the operation at block S3 may include second detecting the assembly yield and supplementing assembly.

In some embodiments, different from the first embodiment of the operation at block S3 in the method for transferring the light-emitting elements 4, in the present embodiment, after driving the third liquid droplet 53 to rotate around the center point Q of the third color pixel group 103, so as to assemble the third color light-emitting element 403 into the assembly groove 21 of the third color pixel group 103, as described in the operation at block S35A, second detecting the assembly yield and supplementing assembly may need to be performed.

As illustrated in FIG. 21, in some embodiments, the operation of second detecting the assembly yield and supplementing assembly, as described in the operation at block S36A, includes the following operations.

At block S361A, the operation of second detecting the assembly yield and supplementing assembly may include detecting whether the assembly groove 21 of the third color pixel group 103 is assembled with the third color light-emitting element 403.

In some embodiments, the operation at block S361A may refer to the relevant content of the operation at block S331A, which may not be repeated here.

At block S362A, the operation of second detecting the assembly yield and supplementing assembly may include supplementing the assembly of the third color light-emitting element 403 into the assembly groove 21 of the third color pixel group 103 that has not been assembled with the third color light-emitting element 403 by using the microfluidic transfer substrate 100.

In some embodiments, the operation at block S362A may refer to the relevant content of the operation at block S322A, which may not be repeated here.

In some embodiments, the structure corresponding to the operation at block S362A is illustrated in FIG. 22.

In some embodiments, after the operation at block S36A, the structure illustrated in FIG. 15 may be obtained.

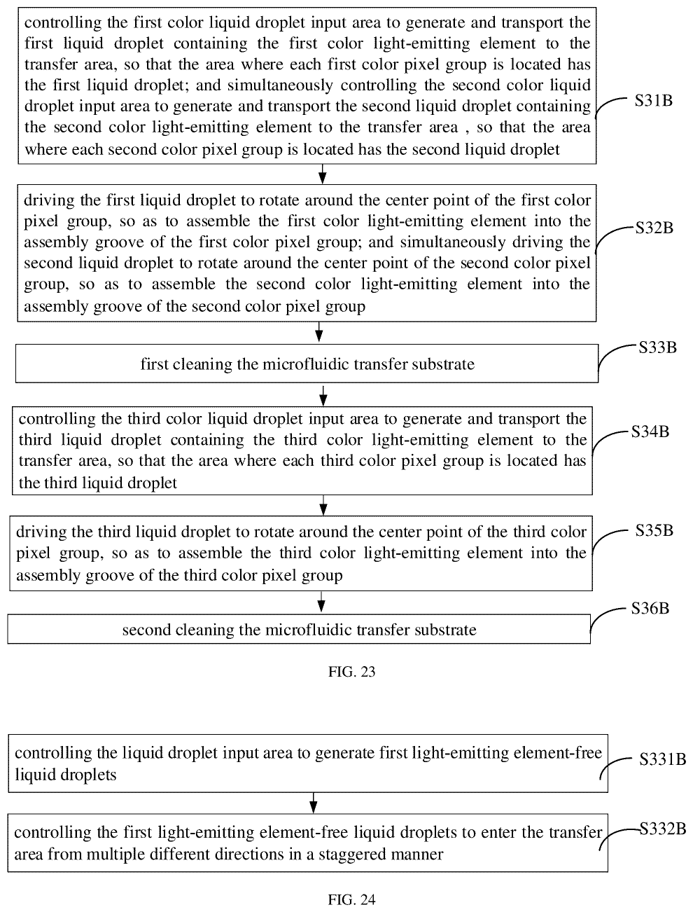

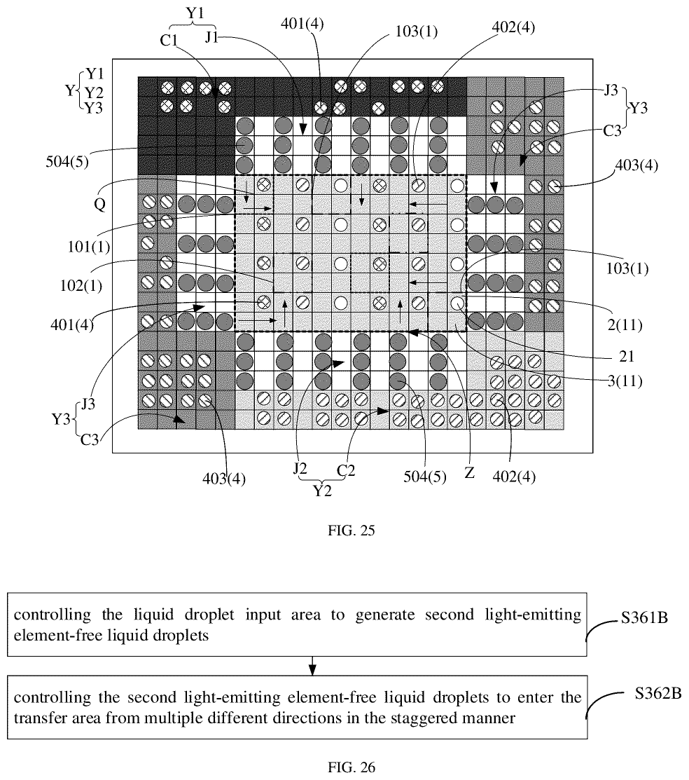

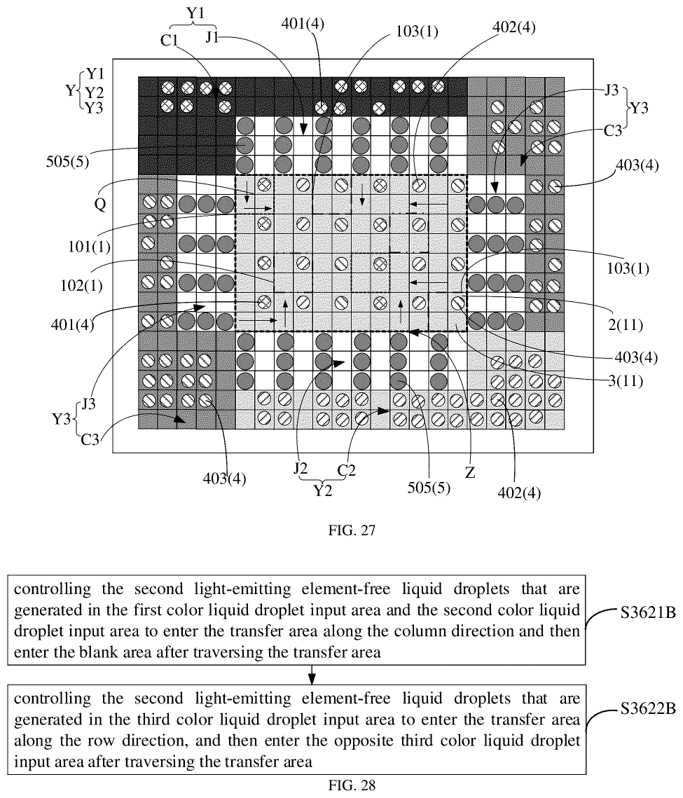

As illustrated in FIGS. 23 to 28, FIG. 23 is a flowchart of a third embodiment of the operation at block S3 in the method for transferring the light-emitting elements of FIG. 9. FIG. 24 is a flowchart of an embodiment of an operation at block S33B of FIG. 23. FIG. 25 is a structural schematic view of a structure corresponding to an operation at block S332B of FIG. 24. FIG. 26 is a flowchart of an embodiment of an operation at block S36B of FIG. 23. FIG. 27 is a structural schematic view of a structure corresponding to an operation at block S362B of FIG. 26. FIG. 28 is a flowchart of the operation at block S362B of FIG. 26.

In some embodiments, as illustrated in FIG. 23, the operation at block S3 in the method for transferring the light-emitting elements 4, which involves controlling the first color liquid droplet input area Y1, the second color liquid droplet input area Y2, and the third color liquid droplet input area Y3 to respectively generate and transport the liquid droplet 5 containing corresponding color light-emitting element 4 to the transfer area Z, controlling the liquid droplet 5 containing corresponding color light-emitting element 4 to enter the area where the corresponding color pixel group 1 is located, and driving the liquid droplet 5 containing corresponding color light-emitting element 4 to rotate around the center point Q of the corresponding color pixel group 1, so as to assemble the light-emitting element 4 into the assembly groove 21 of the corresponding color pixel group 1, includes the following operations.

At block S31B, the operation at block S3 may include controlling the first color liquid droplet input area Y1 to generate and transport the first liquid droplet 51 containing the first color light-emitting element 401 to the transfer area Z, so that the area where each first color pixel group 101 is located has the first liquid droplet 51; and simultaneously controlling the second color liquid droplet input area Y2 to generate and transport the second liquid droplet 52 containing the second color light-emitting element 402 to the transfer area Z, so that the area where each second color pixel group 102 is located has the second liquid droplet 52.

In some embodiments, the operation at block S31B is the same as the operation at block S31 in the first embodiment of the operation at block S3 in the method for transferring the light-emitting elements 4, which may not be repeated here.

At block S32B, the operation at block S3 may include driving the first liquid droplet 51 to rotate around the center point Q of the first color pixel group 101, so as to assemble the first color light-emitting element 401 into the assembly groove 21 of the first color pixel group 101; and simultaneously driving the second liquid droplet 52 to rotate around the center point Q of the second color pixel group 102, so as to assemble the second color light-emitting element 402 into the assembly groove 21 of the second color pixel group 102.

In some embodiments, the operation at block S32B is the same as the operation at block S32 in the first embodiment of the operation at block S3 in the method for transferring the light-emitting elements 4, which may not be repeated here.

At block S33B, the operation at block S3 may include first cleaning the microfluidic transfer substrate 100.

In some embodiments, different from the first embodiment of the operation at block S3 in the method for transferring the light-emitting elements 4, in the present embodiment, before controlling the third color liquid droplet input area Y3 to generate and transport the third liquid droplet 53 containing the third color light-emitting element 403 to the transfer area Z, so that the area where each third color pixel group 103 is located has the third liquid droplet 53, first cleaning the microfluidic transfer substrate 100 as described in the operation at block S33B may need to be performed. Before transporting the third liquid droplet 53 containing the third color light-emitting element 403 to the transfer area Z, the transfer area Z is cleaned, which may remove the first color light-emitting element 401 and the second color light-emitting element 402 in the transfer area Z that have not been assembled into the assembly grooves 21. This prevents some first color light-emitting elements 401 and some second color light-emitting elements 402 from remaining in the transport channels in the transfer area Z, which could otherwise affect the subsequent transport and assembly of the third liquid droplet 53 containing the third color light-emitting element 403. By performing first cleaning of the microfluidic transfer substrate 100, the assembly efficiency and the transport efficiency of the third color light-emitting elements 403 may be improved, and the assembly accuracy may be improved.

In some embodiments, as illustrated in FIG. 24, the operation of first cleaning the microfluidic transfer substrate 100, as described in the operation at block S33B, includes the following operations.

At block S331B, the operation of first cleaning the microfluidic transfer substrate 100 may include controlling the liquid droplet input area Y to generate first light-emitting element-free liquid droplets 504.

In some embodiments, the liquid droplet input area Y is controlled to generate the first light-emitting element-free liquid droplets 504. In some embodiments, any one or more of the first color liquid droplet input area Y1, the second color liquid droplet input area Y2, and the third color liquid droplet input area Y3 may be controlled to generate the first light-emitting element-free liquid droplets 504.

At block S332B, the operation of first cleaning the microfluidic transfer substrate 100 may include controlling the first light-emitting element-free liquid droplets 504 to enter the transfer area Z from multiple different directions in a staggered manner.

In some embodiments, the first light-emitting element-free liquid droplets 504 are controlled to enter the transfer area Z from multiple different directions in the staggered manner, so that the transfer area Z of the microfluidic transfer substrate 100 is cleaned by the first light-emitting element-free liquid droplets 504. The first color light-emitting element 401 or the second color light-emitting element 402 left on the transport channel in the transfer area Z that is not assembled into the assembly groove 21 is removed, which prevents the first color light-emitting element 401 or the second color light-emitting element 402 that is not assembled into the assembly groove 21 from blocking the transport channel or affecting the subsequent movement of the third liquid droplet 53 containing the third color light-emitting element 403.

As illustrated in FIG. 25, the first light-emitting element-free liquid droplet 504 is generated in each of the first color liquid droplet input area Y1, the second color liquid droplet input area Y2, and the third color liquid droplet input area Y3. The first light-emitting element-free liquid droplets 504 are controlled to enter the transfer area Z from the first color liquid droplet input area Y1, the second color liquid droplet input area Y2, and the third color liquid droplet input area Y3 in the staggered manner along multiple different directions, such as the row direction or the column direction, so that the transfer area Z is cleaned. In some embodiments, after detecting that the assembly yield of the first color light-emitting elements 401 and the second color light-emitting elements 402 is qualified, the microfluidic transfer substrate 100 may be cleaned.

In some embodiments, the microfluidic transfer substrate 100 further includes the blank area K (as illustrated in FIG. 7), and the blank area K is disposed around the transfer area Z and connected to the transfer area Z. In some embodiments, the operation of controlling the first light-emitting element-free liquid droplets 504 to enter the transfer area Z from multiple different directions in the staggered manner, as described in the operation at block S332B, includes: controlling the first light-emitting element-free liquid droplets 504 to enter the transfer area Z from multiple different directions, and then enter the blank area K after traversing the transfer area Z.

In some embodiments, the microfluidic transfer substrate 100 also includes the blank area K that is disposed around the transfer area Z and connected to the transfer area Z, the first light-emitting element-free liquid droplets 504 may be controlled to enter the transfer area Z from multiple different directions and then enter the blank area K after traversing the transfer area Z. The blank area K is configured to accommodate the liquid droplet 5 that has already cleaned the transfer area Z. This may prevent the first light-emitting element-free liquid droplets 504 from directly returning to the liquid droplet input area Y after cleaning the transfer area Z. In a case where the liquid droplet 5, after cleaning the transfer area Z, contains any one or two of the first color light-emitting element 401 and the second color light-emitting element 402 that are left in the transfer area Z, the liquid droplet input area Y may be contaminated with the light-emitting elements 4 with different colors. This contamination would affect the subsequent assembly of the light-emitting elements 4 with different colors. By allowing the liquid droplet 5 after cleaning to enter the blank area K, the assembly yield of the light-emitting elements 4 with different colors may be improved.

In some embodiments, after the first light-emitting element-free liquid droplet 504 cleans the transfer area Z, the liquid droplet 5 contains the unassembled first color light-emitting element 401 that is left in the transfer area Z. In a case where the first light-emitting element-free liquid droplet 504 directly traverses the transfer area Z and returns to the second color liquid droplet input area Y2, it may cause the liquid in the second color liquid droplet input area Y2 to be mixed with the first color light-emitting element 401, affecting the subsequent assembly of the second color light-emitting element 402, and making it easy to mistakenly assemble the first color light-emitting element 401 into the assembly groove 21 of the second color pixel group 102. By setting the blank area K to accommodate the liquid droplet 5 after cleaning the transfer area Z, the above-mentioned problems may be avoided and the assembly yield may be improved.

At block S34B, the operation at block S3 may include controlling the third color liquid droplet input area Y3 to generate and transport the third liquid droplet 53 containing the third color light-emitting element 403 to the transfer area Z, so that the area where each third color pixel group 103 is located has the third liquid droplet 53.

In some embodiments, the operation at block S34B is the same as the operation at block S33 in the first embodiment of the operation at block S3 in the method for transferring the light-emitting elements 4, which may not be repeated here.

At block S35B, the operation at block S3 may include driving the third liquid droplet 53 to rotate around the center point Q of the third color pixel group 103, so as to assemble the third color light-emitting element 403 into the assembly groove 21 of the third color pixel group 103.

In some embodiments, the operation at block S35B is the same as the operation at block S34 in the first embodiment of the operation at block S3 in the method for transferring the light-emitting elements 4, which may not be repeated here.

At block S36B, the operation at block S3 may include second cleaning the microfluidic transfer substrate 100.

In some embodiments, different from the first embodiment of the operation at block S3 in the method for transferring the light-emitting elements 4, in the present embodiment, after driving the third liquid droplet 53 to rotate around the center point Q of the third color pixel group 103, so as to assemble the third color light-emitting element 403 into the assembly groove 21 of the third color pixel group 103, as described in the operation at block S35B, the operation of second cleaning the microfluidic transfer substrate 100 may need to be performed.

As illustrated in FIG. 26, in some embodiments, the operation of second cleaning the microfluidic transfer substrate 100, as described in the operation at block S36B, includes the following operations.

At block S361B, the operation of second cleaning the microfluidic transfer substrate 100 may include controlling the liquid droplet input area Y to generate second light-emitting element-free liquid droplets 505.

In some embodiments, the liquid droplet input area Y is controlled to generate the second light-emitting element-free liquid droplets 505. In some embodiments, any one or more of the first color liquid droplet input area Y1, the second color liquid droplet input area Y2, and the third color liquid droplet input area Y3 may be controlled to generate the second light-emitting element-free liquid droplets 505.

At block S362B, the operation of second cleaning the microfluidic transfer substrate 100 may include controlling the second light-emitting element-free liquid droplets 505 to enter the transfer area Z from multiple different directions in the staggered manner.

In some embodiments, the second light-emitting element-free liquid droplets 505 are controlled to enter the transfer area Z from multiple different directions in the staggered manner, so that the transfer area Z of the microfluidic transfer substrate 100 is cleaned by the second light-emitting element-free liquid droplets 505. The third color light-emitting element 403 left on the transport channel in the transfer area Z that is not assembled into the assembly groove 21 in the transfer area Z is removed. It may prevent the third color light-emitting elements 403 from being left in the transfer area Z of the microfluidic transfer substrate 100, which could otherwise affect the transfer effect of the light-emitting elements 4 from the microfluidic transfer substrate 100 to the driving backplane.

As illustrated in FIG. 27, the second light-emitting element-free liquid droplets 505 are generated in each of the first color liquid droplet input area Y1, the second color liquid droplet input area Y2, and the third color liquid droplet input area Y3. The second light-emitting element-free liquid droplets 505 are controlled to enter the transfer area Z from the first color liquid droplet input area Y1, the second color liquid droplet input area Y2, and the third color liquid droplet input area Y3 in the staggered manner along multiple different directions, such as the row direction or the column direction, so that the transfer area Z is cleaned.

In some embodiments, the microfluidic transfer substrate 100 further includes the blank area K (as illustrated in FIG. 7), the blank area is disposed around the transfer area Z and connected to the transfer area Z. As illustrated in FIG. 28, in some embodiments, the operation of controlling the second light-emitting element-free liquid droplets 505 to enter the transfer area Z from multiple different directions in the staggered manner, as described in the operation at block S362B, includes the following operations.

At block S3621B, the operation of controlling the second light-emitting element-free liquid droplets 505 to enter the transfer area Z from multiple different directions in the staggered manner may include controlling the second light-emitting element-free liquid droplets 505 that are generated in the first color liquid droplet input area Y1 and the second color liquid droplet input area Y2 to enter the transfer area Z along the column direction and then enter the blank area K after traversing the transfer area Z.

In some embodiments, the second light-emitting element-free liquid droplets 505 that are generated in the first color liquid droplet input area Y1 and the second color liquid droplet input area Y2 is controlled to enter the transfer area Z along the column direction and then enter the blank area K after traversing the transfer area Z. Similarly, the blank area K is configured to accommodate the liquid droplet 5 that is formed after the second light-emitting element-free liquid droplet 505 cleans the transfer area Z. It may prevent the liquid droplet 5 from containing the third color light-emitting element 403 that is left on the transport channel in the transfer area Z, after the second light-emitting element-free liquid droplet 505 enters the transfer area Z along the column direction and cleans the transfer area Z. In a case where the liquid droplet 5 directly enters the first color liquid droplet input area Y1 or the second color liquid droplet input area Y2 after traversing the transfer area Z along the column direction, it may cause the liquid in the first color liquid droplet input area Y1 or the second color liquid droplet input area Y2 to be mixed with the third color light-emitting element 403, thereby affecting the subsequent assembly of the first color light-emitting element 401 and the second color light-emitting element 402. By setting the blank area K to accommodate the liquid droplet 5 after second cleaning the transfer area Z, the above-mentioned problems may be avoided, and the assembly yield may be improved.

At block S3622B, the operation of controlling the second light-emitting element-free liquid droplets 505 to enter the transfer area Z from multiple different directions in the staggered manner may include controlling the second light-emitting element-free liquid droplets 505 that are generated in the third color liquid droplet input area Y3 to enter the transfer area Z along the row direction, and then enter the opposite third color liquid droplet input area Y3 after traversing the transfer area Z.

In some embodiments, the second light-emitting element-free liquid droplets 505 that are generated in the third color liquid droplet input area Y3 are controlled to enter the transfer area Z along the row direction, and then enter the opposite third color liquid droplet input area Y3 after traversing the transfer area Z. After the first cleaning of the microfluidic transfer substrate 100 as described in the operation at block S33B, the first color light-emitting element 401 and the second color light-emitting element 402 that are remained in the transfer area Z have been removed by the first light-emitting element-free liquid droplet 504. Therefore, the transfer area Z may only contain the third color light-emitting element 403 that are not assembled into the corresponding assembly groove 21 in the operation at block S35B. That is, only the third color light-emitting element 403 may remain in the transfer area Z, and there may be no longer the first color light-emitting element 401 and the second color light-emitting element 402 in the transfer area Z. The two third color liquid droplet input areas Y3 are arranged opposite to each other on two sides of the rectangular transfer area Z. The second light-emitting element-free liquid droplet 505 that is generated in the third color liquid droplet input area Y3 is controlled to enter the transfer area Z along the row direction and traverse the transfer area Z, and the second light-emitting element-free liquid droplet 505 that is configured for cleaning the transfer area Z may only contain the third color light-emitting element 403 during the cleaning process. The first color light-emitting element 401 and the second color light-emitting element 402 may not appear on the motion trajectory of second light-emitting element-free liquid droplet 505. Therefore, after the second light-emitting element-free liquid droplet 505 that is generated in the third color liquid droplet input area Y3 enters the transfer area Z along the row direction and traverses the transfer area Z, the second light-emitting element-free liquid droplet 505 may directly enter the other third color liquid droplet input area Y3 on the opposite side. This ensures that the first color light-emitting element 401 and the second color light-emitting element 402 do not located in or do not contaminate the third color liquid droplet input area Y3, which may not affect the subsequent assembly of the third color light-emitting element 403. Moreover, after the cleaned liquid droplet 5 returns to the third color liquid droplet input area Y3, the third color light-emitting element 403 left in the transfer area Z may be brought back and be recycled, which is conducive to cost savings.

In some embodiments, the operation at block S3 may simultaneously include first detecting the assembly yield and supplementing assembly, first cleaning the microfluidic transfer substrate 100, second detecting the assembly yield and supplementing assembly, and second cleaning the microfluidic transfer substrate 100. Alternatively, the operation at block S3 may only include any one or more of the above operations, which is not limited in the present disclosure and may be designed as needed.

By the method for transferring the light-emitting elements 4 in the present disclosure, transfer of the light-emitting elements 4 with three different colors to the driving backplane may be achieved, solving the problem of difficulty in simultaneously transferring multiple light-emitting elements 4 with different colors to the driving backplane in the related art, thereby achieving mass transfer of the light-emitting elements 4 with three different colors.

Different from the related art, the effects of the present disclosure are as follows. The present disclosure provides the microfluidic transfer substrate and the method for transferring the light-emitting elements. The microfluidic transfer substrate includes a transfer area and a liquid droplet input area. The transfer area includes a plurality of pixel groups. Each pixel group includes at least three first pixel units, and the first pixel units of the plurality of pixel groups are arranged around a center point; one first pixel unit of each pixel group serves as a first microfluidic pixel and a surface of the first microfluidic pixel defines an assembly groove, and the other first pixel units serve as second microfluidic pixels and a surface of each second microfluidic pixel is free of the assembly groove; and the plurality of pixel groups include first color pixel groups, second color pixel groups, and third color pixel groups. The liquid droplet input area is disposed around the transfer area. The liquid droplet input area includes a first color liquid droplet input area, a second color liquid droplet input area, and a third color liquid droplet input area that are distributed along circumference of the transfer area; and the first color liquid droplet input area is configured to generate and transport a first liquid droplet containing a first color light-emitting element to the transfer area, the second color liquid droplet input area is configured to generate and transport a second liquid droplet containing a second color light-emitting element to the transfer area, and the third color liquid droplet input area is configured to generate and transport a third liquid droplet containing a third color light-emitting element to the transfer area. By the above settings, the problem of difficulty in simultaneously transferring multiple light-emitting elements with different colors to the driving backplane in related art may be solved, thereby achieving mass transfer of the light-emitting elements with three different colors.

The above descriptions are only some embodiments of the present disclosure, and are not intended to limit the protection scope of the present disclosure. Any equivalent structure or equivalent flow transformation made by using the contents and the accompanying drawings of the present disclosure, or directly or indirectly applied to other related technical fields, is included in the protection scope of the present disclosure.

1. A microfluidic transfer substrate, comprising:
a transfer area, comprising a plurality of pixel groups; wherein each pixel group comprises at least three first pixel units, and the first pixel units of each pixel group are arranged around a center point; one first pixel unit of each pixel group serves as a first microfluidic pixel and a surface of the first microfluidic pixel defines an assembly groove, and the other first pixel units serve as second microfluidic pixels and a surface of each second microfluidic pixel is free of the assembly groove; and the plurality of pixel groups comprise first color pixel groups, second color pixel groups, and third color pixel groups; and
a liquid droplet input area, disposed around the transfer area;
wherein the liquid droplet input area comprises a first color liquid droplet input area, a second color liquid droplet input area, and a third color liquid droplet input area that are distributed along circumference of the transfer area; and the first color liquid droplet input area is configured to generate and transport a first liquid droplet containing a first color light-emitting element to the transfer area, the second color liquid droplet input area is configured to generate and transport a second liquid droplet containing a second color light-emitting element to the transfer area, and the third color liquid droplet input area is configured to generate and transport a third liquid droplet containing a third color light-emitting element to the transfer area.

2. The microfluidic transfer substrate according to claim 1, wherein the plurality of pixel groups are arranged in a two-dimensional array, each pixel group comprises four first pixel units, and the four first pixel units of the same pixel group are arranged to form a two-dimensional array with two rows and two columns;
the liquid droplet input area comprises a plurality of second pixel units, and all first pixel units in the transfer area and all second pixel units in the liquid droplet input area are arranged in the two-dimensional array;
the first microfluidic pixels of the same column of pixel groups are all belong to the first pixel units of the same column; and
the first color liquid droplet input area and the second color liquid droplet input area are located on two opposite sides of the transfer area along a column direction, respectively.

3. The microfluidic transfer substrate according to claim 2, wherein
a size of the transfer area along a row direction is greater than a size of the transfer area along the column direction, and two third color liquid droplet input areas are located on two opposite sides of the transfer area along the row direction, respectively.

4. The microfluidic transfer substrate according to claim 3, wherein
the first color liquid droplet input area comprises a first color liquid droplet generation area and a first color liquid droplet entry area that is connected to the first color liquid droplet generation area and the transfer area;
the second color liquid droplet input area comprises a second color liquid droplet generation area and a second color liquid droplet entry area that is connected to the second color liquid droplet generation area and the transfer area; and
the third color liquid droplet input area comprises a third color liquid droplet generation area and a third color liquid droplet entry area that is connected to the third color liquid droplet generation area and the transfer area.

5. The microfluidic transfer substrate according to claim 4, wherein
the transfer area is rectangular, and comprises a first long side and a second long side opposite to each other, as well as a first short side and a second short side opposite to each other;
the first color liquid droplet entry area is connected to the transfer area on the first long side; and a part of the first color liquid droplet generation area is located on a side of the first color liquid droplet entry area away from the transfer area, and the other part of the first color liquid droplet generation area is located in an angle area that is defined by an extension line of the first long side and an extension line of the first short side;
the second color liquid droplet entry area is connected to the transfer area on the second long side; and a part of the second color liquid droplet generation area is located on a side of the second color liquid droplet entry area away from the transfer area, and the other part of the second color liquid droplet generation area is located in an angle area defined by an extension line of the second long side and an extension line of the second short side;
in one of two third color liquid droplet input areas, the third color liquid droplet entry area is connected to the transfer area on the first short side; and a part of the third color liquid droplet generation area is located on a side of the third color liquid droplet entry area away from the transfer area, and the other part of the third color liquid droplet generation area is located in an angle area that is defined by the extension line of the second long side and the extension line of the first short side;
in the other of the two third color liquid droplet input areas, the third color liquid droplet entry area is connected to the transfer area on the second short side; and a part of the third color liquid droplet generation area is located on a side of the third color liquid droplet entry area away from the transfer area, and the other part of the third color liquid droplet generation area is located in an angle area that is defined by the extension line of the first long side and the extension line of the second short side.

6. The microfluidic transfer substrate according to claim 1, wherein the microfluidic transfer substrate further comprises:
a blank area, disposed around the transfer area and connected to the transfer area.

7. A method for transferring light-emitting elements, comprising:
providing a microfluidic transfer substrate, comprising:
a transfer area, comprising a plurality of pixel groups; wherein each pixel group comprises at least three first pixel units, and the first pixel units of each pixel group are arranged around a center point; one first pixel unit of each pixel group serves as a first microfluidic pixel and a surface of the first microfluidic pixel defines an assembly groove, and the other first pixel units serve as second microfluidic pixels and a surface of each second microfluidic pixel is free of the assembly groove; and the plurality of pixel groups comprise first color pixel groups, second color pixel groups, and third color pixel groups; and
a liquid droplet input area, disposed around the transfer area;
wherein the liquid droplet input area comprises a first color liquid droplet input area, a second color liquid droplet input area, and a third color liquid droplet input area that are distributed along circumference of the transfer area; and the first color liquid droplet input area is configured to generate and transport a first liquid droplet containing a first color light-emitting element to the transfer area, the second color liquid droplet input area is configured to generate and transport a second liquid droplet containing a second color light-emitting element to the transfer area, and the third color liquid droplet input area is configured to generate and transport a third liquid droplet containing a third color light-emitting element to the transfer area;
placing liquid and corresponding color light-emitting element in the first color liquid droplet input area, the second color liquid droplet input area, and the third color liquid droplet input area, respectively; and
controlling the first color liquid droplet input area, the second color liquid droplet input area, and the third color liquid droplet input area to generate and transport liquid droplets containing corresponding color light-emitting elements to the transfer area, controlling each of the liquid droplets containing corresponding color light-emitting elements to enter an area where the corresponding color pixel group is located, and driving each of the liquid droplets containing corresponding color light-emitting elements to rotate around a center point of the corresponding color pixel group, so as to assemble each of the light-emitting elements into the assembly groove of the corresponding color pixel group.

8. The method for transferring the light-emitting elements according to claim 7, wherein
the plurality of pixel groups are arranged in a two-dimensional array, each pixel group comprises four first pixel units, and the four first pixel units of the same pixel group are arranged to form a two-dimensional array with two rows and two columns;
the liquid droplet input area comprises a plurality of second pixel units, and all first pixel units in the transfer area and all second pixel units in the liquid droplet input area are arranged in the two-dimensional array;
the first microfluidic pixels of the same column of pixel groups are all belong to the first pixel units of the same column; and
the first color liquid droplet input area and the second color liquid droplet input area are located on two opposite sides of the transfer area along a column direction, respectively.

9. The method for transferring the light-emitting elements according to claim 8, wherein
a size of the transfer area along a row direction is greater than a size of the transfer area along the column direction, and two third color liquid droplet input areas are located on two opposite sides of the transfer area along the row direction, respectively.

10. The method for transferring the light-emitting elements according to claim 9, wherein
the first color liquid droplet input area comprises a first color liquid droplet generation area and a first color liquid droplet entry area that is connected to the first color liquid droplet generation area and the transfer area;
the second color liquid droplet input area comprises a second color liquid droplet generation area and a second color liquid droplet entry area that is connected to the second color liquid droplet generation area and the transfer area; and
the third color liquid droplet input area comprises a third color liquid droplet generation area and a third color liquid droplet entry area that is connected to the third color liquid droplet generation area and the transfer area.

11. The method for transferring the light-emitting elements according to claim 10, wherein
the transfer area is rectangular, and comprises a first long side and a second long side opposite to each other, as well as a first short side and a second short side opposite to each other;
the first color liquid droplet entry area is connected to the transfer area on the first long side; and a part of the first color liquid droplet generation area is located on a side of the first color liquid droplet entry area away from the transfer area, and the other part of the first color liquid droplet generation area is located in an angle area that is defined by an extension line of the first long side and an extension line of the first short side;
the second color liquid droplet entry area is connected to the transfer area on the second long side; and a part of the second color liquid droplet generation area is located on a side of the second color liquid droplet entry area away from the transfer area, and the other part of the second color liquid droplet generation area is located in an angle area defined by an extension line of the second long side and an extension line of the second short side;
in one of two third color liquid droplet input areas, the third color liquid droplet entry area is connected to the transfer area on the first short side; and a part of the third color liquid droplet generation area is located on a side of the third color liquid droplet entry area away from the transfer area, and the other part of the third color liquid droplet generation area is located in an angle area that is defined by the extension line of the second long side and the extension line of the first short side;
in the other of the two third color liquid droplet input areas, the third color liquid droplet entry area is connected to the transfer area on the second short side; and a part of the third color liquid droplet generation area is located on a side of the third color liquid droplet entry area away from the transfer area, and the other part of the third color liquid droplet generation area is located in an angle area that is defined by the extension line of the first long side and the extension line of the second short side.

12. The method for transferring the light-emitting elements according to claim 7, wherein the microfluidic transfer substrate further comprises:
a blank area, disposed around the transfer area and connected to the transfer area.

13. The method for transferring the light-emitting elements according to claim 7, wherein
the plurality of pixel groups are arranged in a two-dimensional array, each pixel group comprises four first pixel units, and the four first pixel units of the same pixel group are arranged to form a two-dimensional array with two rows and two columns;
the liquid droplet input area comprises a plurality of second pixel units, and all first pixel units in the transfer area and all second pixel units in the liquid droplet input area are arranged in the two-dimensional array;
the first microfluidic pixels of the same column of pixel groups are all belong to the first pixel units of the same column; and
the first color liquid droplet input area and the second color liquid droplet input area are located on two opposite sides of the transfer area along a column direction, respectively;
the controlling the first color liquid droplet input area, the second color liquid droplet input area, and the third color liquid droplet input area to generate and transport liquid droplets containing corresponding color light-emitting elements to the transfer area, controlling each of the liquid droplets containing corresponding color light-emitting elements to enter an area where the corresponding color pixel group is located, and driving each of the liquid droplets containing corresponding color light-emitting elements to rotate around a center point of the corresponding color pixel group, so as to assemble each of the light-emitting elements into the assembly groove of the corresponding color pixel group, comprises:
controlling the first color liquid droplet input area to generate and transport the first liquid droplet containing the first color light-emitting element to the transfer area, so that the area where each of the first color pixel groups is located has the first liquid droplet; and simultaneously controlling the second color liquid droplet input area to generate and transport the second liquid droplet containing the second color light-emitting element to the transfer area, so that the area where each of the second color pixel groups is located has the second liquid droplet;
driving the first liquid droplet to rotate around a center point of each of the first color pixel groups, so as to assemble the first color light-emitting element into the assembly groove of each of the first color pixel groups; and simultaneously driving the second liquid droplet to rotate around a center point of the second color pixel group, so as to assemble the second color light-emitting element into the assembly groove of each of the second color pixel groups;
controlling the third color liquid droplet input area to generate and transport the third liquid droplet containing the third color light-emitting element to the transfer area, so that the area where each of the third color pixel groups is located has the third liquid droplet; and
driving the third liquid droplet to rotate around a center point of the third color pixel group, so as to assemble the third color light-emitting element into the assembly groove of each of the third color pixel groups.

14. The method for transferring the light-emitting elements according to claim 13, wherein
a size of the transfer area along a row direction is greater than a size of the transfer area along the column direction, and two third color liquid droplet input areas are located on two opposite sides of the transfer area along the row direction, respectively.

15. The method for transferring the light-emitting elements according to claim 14, wherein
the first color liquid droplet input area comprises a first color liquid droplet generation area and a first color liquid droplet entry area that is connected to the first color liquid droplet generation area and the transfer area;
the second color liquid droplet input area comprises a second color liquid droplet generation area and a second color liquid droplet entry area that is connected to the second color liquid droplet generation area and the transfer area; and
the third color liquid droplet input area comprises a third color liquid droplet generation area and a third color liquid droplet entry area that is connected to the third color liquid droplet generation area and the transfer area.

16. The method for transferring the light-emitting elements according to claim 15, wherein
the transfer area is rectangular, and comprises a first long side and a second long side opposite to each other, as well as a first short side and a second short side opposite to each other;
the first color liquid droplet entry area is connected to the transfer area on the first long side; and a part of the first color liquid droplet generation area is located on a side of the first color liquid droplet entry area away from the transfer area, and the other part of the first color liquid droplet generation area is located in an angle area that is defined by an extension line of the first long side and an extension line of the first short side;
the second color liquid droplet entry area is connected to the transfer area on the second long side; and a part of the second color liquid droplet generation area is located on a side of the second color liquid droplet entry area away from the transfer area, and the other part of the second color liquid droplet generation area is located in an angle area defined by an extension line of the second long side and an extension line of the second short side;
in one of two third color liquid droplet input areas, the third color liquid droplet entry area is connected to the transfer area on the first short side; and a part of the third color liquid droplet generation area is located on a side of the third color liquid droplet entry area away from the transfer area, and the other part of the third color liquid droplet generation area is located in an angle area that is defined by the extension line of the second long side and the extension line of the first short side;
in the other of the two third color liquid droplet input areas, the third color liquid droplet entry area is connected to the transfer area on the second short side; and a part of the third color liquid droplet generation area is located on a side of the third color liquid droplet entry area away from the transfer area, and the other part of the third color liquid droplet generation area is located in an angle area that is defined by the extension line of the first long side and the extension line of the second short side.

17. The method for transferring the light-emitting elements according to claim 13, wherein
before the controlling the third color liquid droplet input area to generate and transport the third liquid droplet containing the third color light-emitting element to the transfer area, so that the area where each of the third color pixel groups is located has the third liquid droplet, the method for transferring the light-emitting elements further comprises: first detecting assembly yield and supplementing assembly; and
after the driving the third liquid droplet to rotate around a center point of the third color pixel group, so as to assemble the third color light-emitting element into the assembly groove of each of the third color pixel groups, the method for transferring the light-emitting elements further comprises:
second detecting assembly yield and supplementing assembly.

18. The method for transferring the light-emitting elements according to claim 13, wherein
before the controlling the third color liquid droplet input area to generate and transport the third liquid droplet containing the third color light-emitting element to the transfer area, so that the area where each of the third color pixel groups is located has the third liquid droplet, the method for transferring the light-emitting elements further comprises: first cleaning the microfluidic transfer substrate; and the first cleaning the microfluidic transfer substrate, comprises:
controlling the liquid droplet input area to generate first light-emitting element-free liquid droplets;
controlling the first light-emitting element-free liquid droplets to enter the transfer area from a plurality of different directions in a staggered manner;
after the driving the third liquid droplet to rotate around a center point of the third color pixel group, so as to assemble the third color light-emitting element into the assembly groove of each of the third color pixel groups, the method for transferring the light-emitting elements further comprises: second cleaning the microfluidic transfer substrate; and the second cleaning the microfluidic transfer substrate, comprises:
controlling the liquid droplet input area to generate second light-emitting element-free liquid droplets; and
controlling the second light-emitting element-free liquid droplets to enter the transfer area from the plurality of different directions in the staggered manner.

19. The method for transferring the light-emitting elements according to claim 18, wherein
the microfluidic transfer substrate further comprises a blank area disposed around the transfer area and connected to the transfer area;
the controlling the first light-emitting element-free liquid droplets to enter the transfer area from a plurality of different directions in a staggered manner, comprises:
controlling the first light-emitting element-free liquid droplets to enter the transfer area from the plurality of different directions in the staggered manner, and then enter the blank area after traversing the transfer area;
the controlling the second light-emitting element-free liquid droplets to enter the transfer area from the plurality of different directions in the staggered manner, comprises:
controlling the second light-emitting element-free liquid droplets that are generated in the first color liquid droplet input area and the second color liquid droplet input area to enter the transfer area along a column direction, and then enter the blank area after traversing the transfer area; and
controlling the second light-emitting element-free liquid droplets that are generated in one third color liquid droplet input area to enter the transfer area along a row direction, and then enter the other third color liquid droplet input area that is opposite to the one third color liquid droplet input area after traversing the transfer area.

20. A microfluidic transfer substrate, comprising:
a transfer area, comprising a plurality of pixel groups; wherein each pixel group comprises at least three first pixel units, and the first pixel units of each pixel group are arranged around a center point; one first pixel unit of each pixel group serves as a first microfluidic pixel and a surface of the first microfluidic pixel defines an assembly groove, and the other first pixel units serve as second microfluidic pixels and a surface of each second microfluidic pixel is free of the assembly groove; and the plurality of pixel groups comprise first color pixel groups, second color pixel groups, and third color pixel groups; and
a liquid droplet input area, comprising a first color liquid droplet input area, a second color liquid droplet input area, and a third color liquid droplet input area; wherein the first color liquid droplet input area is configured to generate and transport a first liquid droplet containing a first color light-emitting element to the transfer area, the second color liquid droplet input area is configured to generate and transport a second liquid droplet containing a second color light-emitting element to the transfer area, and the third color liquid droplet input area is configured to generate and transport a third liquid droplet containing a third color light-emitting element to the transfer area.
